(19) United States
(12) Patent Application Publication
(10) Pub. No.: US 2026/0101739 A1
(43) Pub. Date: Apr. 9, 2026

(54) DEVICE PACKAGE

(71) Applicant: AP Memory Technology Corporation, Hsinchu County (TW)

(72) Inventors: WenLiang Chen, HsinChu (TW); Chin-Hung Liu, HsinChu (TW); Shih-Yao Chen, HsinChu (TW)

(73) Assignee: AP Memory Technology Corporation, Hsinchu County (TW)

(21) Appl. No.: 19/283,252

(22) Filed: Jul. 29, 2025

Related U.S. Application Data
(60) Provisional application No. 63/704,030, filed on Oct. 7, 2024.

(51) Int. Cl. H01L 23/48; H01L 21/768; H01L 23/00; H01L 23/522; H01L 23/528; H01L 25/065; H10D 80/30

(52) U.S. Cl. CPC H10W 20/20; H10W 20/435; H10W 20/496; H10W 20/497; H10W 90/00; H10D 80/30; H10W 20/023; H10W 70/6528; H10W 90/26; H10W 90/297; H10W 90/792

(57) ABSTRACT

A device package includes a first tier, a second tier stacked upon the first tier, and a through tier via unitarily penetrating through the first and second tiers. The first tier includes a first device and a first interconnect structure electrically coupled to the first device, the first interconnect structure includes a first metal layer, and the first metal layer includes a first connection branch. The second tier includes a second device and a second interconnect structure electrically coupled to the second device, the second interconnect structure includes a second metal layer, and the second metal layer includes a second connection branch. The through tier via is electrically coupled to the first and second connection branches.

### CROSS-REFERENCE TO RELATED APPLICATION

This application claims the priority benefit of U.S. provisional application Ser. No. 63/704,030, filed on Oct. 7, 2024. The entirety of the above-mentioned patent application is hereby incorporated by reference herein and made a part of this specification.

### BACKGROUND

### Technical Field

The present disclosure relates to a device package, particularly, the device package includes one or more through tier vias for electrically connecting the stacked tiers.

### Description of Related Art

Three-dimensional (3D) device packages generally include multiple tiers stacked upon of each other. The upper tier in a 3D device package can be connected to the lower tier using a variety of configurations, including through-silicon vias (TSVs) and/or hybrid bonding. Fabrication of 3D device packages seeks to be more efficient and cost effective, while providing more devices in smaller packages. As a result, there is continuous effort in developing new mechanisms of forming device packages with better reliability and performance.

### SUMMARY

According to an embodiment of the disclosure, a device package includes a first tier, a second tier stacked upon the first tier, and a through tier via unitarily penetrating through the first and second tiers. The first tier includes a first device and a first interconnect structure electrically coupled to the first device, the first interconnect structure includes a first metal layer, and the first metal layer includes a first connection branch. The second tier includes a second device and a second interconnect structure electrically coupled to the second device, the second interconnect structure includes a second metal layer, and the second metal layer includes a second connection branch. The through tier via is electrically coupled to the first and second connection branches.

According to another embodiment of the disclosure, a device package includes a first bonding pair, N second bonding pairs stacked upon the first bonding pair, and a through tier via. The first bonding pair includes a bottom tier and a first tier stacked upon the bottom tier, the bottom tier includes a bottom device and a front-side RDL electrically coupled to the bottom device, the first tier includes a first device and a first connection branch electrically coupled to the first device. Each of the N second bonding pairs includes a second tier and a third tier stacked upon the second tier, the second tier includes a second device and a second connection branch electrically coupled to the second device, and the third tier includes a third device and a third connection branch electrically coupled to the third device. The through tier via unitarily penetrates through the N second bonding pairs and the first tier of the first bonding pair, and the through tier via is electrically coupled to the front-side RDL and the first, second, and third connection branches, where N≥1.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1-3 illustrate schematic cross-sectional views of a device package according to various embodiments of the present disclosure.

FIGS. 4A, 4B, 4D-4E, 4G, 4I-4J, and 4L illustrate schematic cross-sectional views of a method for forming a device package according to some embodiments of the present disclosure.

FIGS. 4C, 4F, 4H, and 4K illustrate schematic and exemplary expanded views of FIGS. 4B, 4E, 4G, and 4J, respectively, according to some embodiments of the present disclosure.

FIGS. 5A-5H illustrate schematic cross-sectional views of a method for forming a device package according to some embodiments of the present disclosure.

FIGS. 6A-6H illustrate schematic cross-sectional views of a method for forming a device package according to some embodiments of the present disclosure.

### DESCRIPTION OF THE EMBODIMENTS

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct via, and may also include embodiments in which additional features may be formed between the first and second features, such that the first and second features may not be in direct via. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “below,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

As used herein, the terms such as “first” and “second” describe various elements, components, regions, layers and/or sections, these elements, components, regions, layers and/or sections should not be limited by these terms. These terms may be only used to distinguish one element, component, region, layer or section from another. The terms such as “first” and “second” when used herein do not imply a sequence or order unless clearly indicated by the context.

Three-dimensional integrated circuits (3DICs) were developed, where at least two IC tiers (e.g., wafers or dies) may be stacked. In order to enable the various devices integrated within each stacked tiers, electrical connections are provided that provide conductors between vertical tiers. Through substrate vias (TSVs) are typically fabricated to provide vias filled with conductive materials that pass through the tier to connect with the other TSVs and conductors of the bonded layers. In some comparative embodiments, each tier of the 3DIC includes a substrate, active devices formed in/on the substrate, and an oxide trench formed in the substrate. The TSVs of the 3DIC pass through the oxide trench without contacting the substrate so as to reduce the risk of leakage, and the TSVs also pass through the interconnect dielectric layer of the respective tier to the adjacent tier. However, such configuration of the 3DIC cannot achieve a thinner thickness because the substrate should be contained in each tier. In addition, such configuration of the 3DIC lacks dummy patterns in the oxide trench, which results in non-uniformity issues after performing a planarization process (e.g., chemical mechanical polishing (CMP)) on the TSVs, the oxide trench, and the substrate.

Therefore, in some embodiments of the present disclosure, a device package and a method for forming a device package are provided, where the substrates and the oxide trenches in the overlying tiers over the bottom tier can be removed so as to reduce the overall thickness of the device package. Due to the omission of the oxide trench, the manufacturing steps and cost may be reduced and the issues caused by filling the trench in the substrate to form the oxide trench may also be eliminated. The device package may include one or more through tier via(s) passing through the tiers overlying the bottom tier. Since the thickness of each tier over the bottom tier is reduced, the through tier vias passing through these tiers with the reduced thickness may be shortened, thereby lowering the electrical resistance of the through tier vias. In addition, due to the reduced overall thickness of the device package, the aspect ratio of the respective through tier via may be reduced, and the tighter pitch between adjacent through tier vias and the higher interconnect density may be obtained. Moreover, the through tier vias may only pass through the dielectric materials in each tier overlying the bottom tier; therefore, a more uniform profile of the respective through tier via may be obtained.

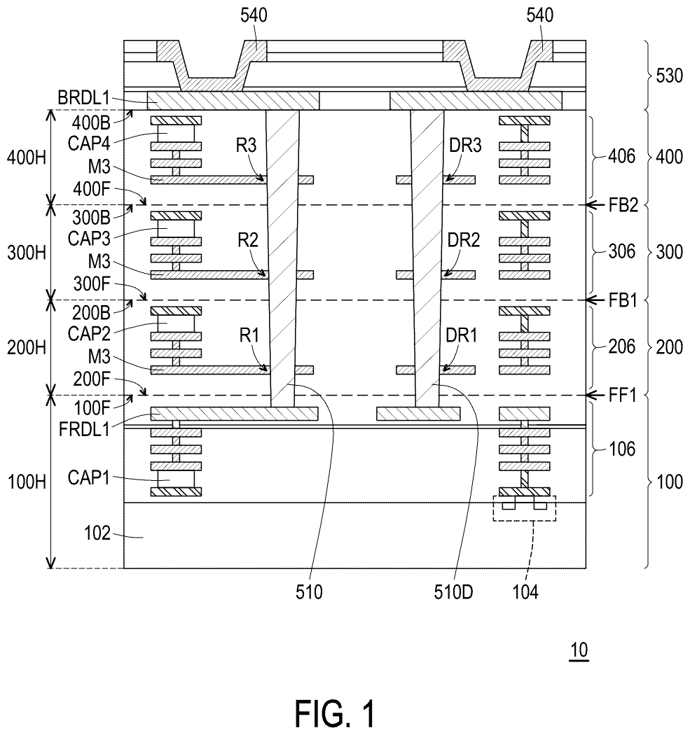

FIGS. 1-3 illustrate schematic cross-sectional views of a device package according to various embodiments of the present disclosure. Referring to FIG. 1, a device package 10 including stacked tiers is provided. It should be noted that the four-tier structure of the device package 10 illustrated in FIG. 1 is merely for illustrative purpose, and the device package may include two tiers, three tiers, or more than four tiers, in accordance with some embodiments. For example, the device package 10 includes a bottom tier 100, a first tier 200 stacked upon and bonded to the bottom tier 100, a second tier 300 stacked upon and bonded to the first tier 200, and a third tier 400 stacked upon and bonded to the second tier 300. The bottom tier 100 includes a bottom substrate 102, one or more bottom device(s) 104 formed in/on the bottom substrate 102, a bottom interconnect structure 106 formed over the bottom substrate 102 and covering the bottom device 104, one or more first device(s) CAP1 formed in the bottom interconnect structure 106. The first device CAP1 may be electrically coupled to the bottom device 104 through the bottom interconnect structure 106. In some embodiments, the bottom device 104 may be referred to as logic devices including the transistors formed on the semiconductor substrate (e.g., the bottom substrate 102). The first device CAP1 may be referred to as passive devices such as capacitors or inductor formed above the bottom substrate 102. In some embodiments, the first device CAP1 is formed within the bottom interconnect structure 106 and does not directly contact with the bottom substrate 102. In some embodiments, the bottom tier 100 may include logic devices, passive devices (e.g., capacitors, inductors), logic devices accompanying with passive devices, and/or the like. In some embodiments, the bottom tier may include logic devices 104 and without the additionally formed passive devices (e.g., the first device CAP1). In some embodiments, the bottom tier 100 may include a front-side redistribution layer FRDL1 in the bottom interconnect structure 106 and electrically coupled to the bottom device 104 and the first device CAP1.

The first tier 200 of the device package 10 may include a first interconnect structure 206 and one or more second device(s) CAP2 formed in the first interconnect structure 206. The first tier 200 includes a front side 200F bonded to a front side 100F of the bottom tier 100 and a back side 200B bonded to a front side 300F of the second tier 300. A front-to-front bonding interface FF1 is formed between the bottom tier 100 and the first tier 200, and a front-to-back bonding interface FB1 is formed between the second tier 300 and the first tier 200. In other words, the bottom tier 100 and the first tier 200 are bonded in a front-to-front configuration, and the second tier 300 and the first tier 200 are bonded in a front-to-back configuration. For example, in the front-to-back configuration, the metal layer M3 in the second tier 300 is proximal to the front-to-back bonding interface FB1, while the metal layer M3 in the first tier 200 is distal to the front-to-back bonding interface FB1. In some embodiments, the metal layer M3 may be referred to as the topmost metal layer in the respective interconnect structure, and proximal to the front side of the respective tier.

The second tier 300 and the third tier 400 are similar to the first tier 200. For example, the second tier 300 includes a second interconnect structure 306 and one or more third device(s) CAP3 formed in the second interconnect structure 306. The third tier 400 may include a third interconnect structure 406 and one or more fourth device(s) CAP4 formed in the third interconnect structure 406. A back side 300B of the second tier 300 is bonded to a front side 400F of the third tier 400 to form a front-to-back bonding interface FB2 therebetween. For example, the second tier 300 and the third tier 400 are bonded in a front-to-back configuration. In some embodiments, the first tier 200, the second tier 300, and the third tier 400 only contain passive devices (e.g., capacitors, inductors, or the like) and are free of active devices. The first tier 200, the second tier 300, and the third tier 400 may each contain devices (e.g., any type of devices formed within Back-End-of-Line (BEOL)) without requirement of substrate. In some embodiments, the first tier 200, the second tier 300, and the third tier 400 are free of Front-End-of-Line (FEOL) devices, which require the substrate, formed therein.

With continued reference to FIG. 1, the first tier 200, the second tier 300, and the third tier 400 may each include one or more connection branch(es) (e.g., R1-R3 and DR1-DR3) in the metal layers (e.g., M3) of the corresponding interconnect structures. The device package 10 may include one or more through dielectric via(s) (TDVs) (e.g., 510 and 510D) passing through the connection branches (e.g., R1-R3 and DR1-DR3) in each of the first tier 200, the second tier 300, and the third tier 400 and landing on the front-side redistribution layer FRDL1 of the bottom tier 100. In some embodiments, the TDVs (510 and/or 510D) are continuously and unitarily extend through at least two stacked tiers. The TDVs (510 and 510D) may be referred to as through tier vias.

In some embodiments, the respective TDV (510 or 510D) is tapered in a direction from the third tier 400 toward the bottom tier 100. In some embodiments, the TDV 510 is in lateral and electrical contact with the connection branch R3 of the third tier 400, the connection branch R2 of the second tier 300, and the connection branch R1 of the first tier 200. The third tier 400, the second tier 300, and the first tier 200 may be electrically coupled to the bottom tier 100 through the TDV 510. In other words, the TDV 510 provides a vertical and electrical connection between the stacked tiers over the bottom tier 100. In some embodiments, the TDV 510D is in lateral contact with the additional connection branch DR3 in the third tier 400, the additional connection branch DR2 in the second tier 300, and the additional connection branch DR1 in the first tier 200. The TDV 510D may be viewed as an additional TDV. In some embodiments, the additional TDV 510D is electrically isolated from the devices (e.g., CAP2, CAP3, and CAP4) and may be used for dummy patterns to improve the etching or chemical-mechanical polishing uniformity during the formation of the TDV 510. In some embodiments, the additional TDV 510D may be used for electrical/signal routings in the device package 10, and the TDV510D may provide direct electrical/signal routing between the bottom tier 100 and the corresponding under-bump metallization pad 540.

With continued reference to FIG. 1, the device package 10 may include a backside redistribution layer BRDL1 formed on the back side 400B of the third tier 400 and connected to the TDVs 510 (and 510D, if desired). The device package 10 may include a passivation structure 530 formed on the back side 400B of the third tier 400 and bury the backside redistribution layer BRDL1 therein. The device package 10 may include one or more under-bump metallization (UBM) pad(s) 540 formed on the backside redistribution layer BRDL1 and covered by the passivation structure 530. At least a portion of the UBM pads 540 is exposed by the passivation structure 530 for further electrical connection. The UBM pads 540 may be electrically coupled to the TDV 510 through the backside redistribution layer BRDL1. The backside redistribution layer BRDL1 and the UBM pads 540 may be collectively viewed as a conductive structure formed over the third tier 400.

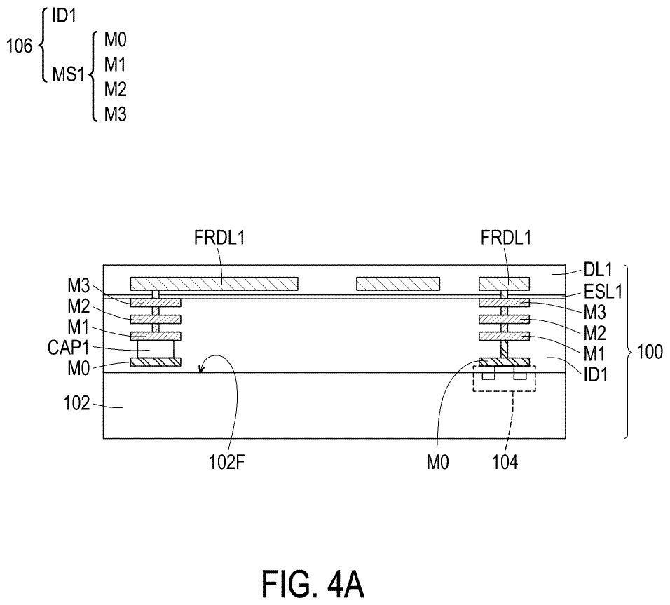

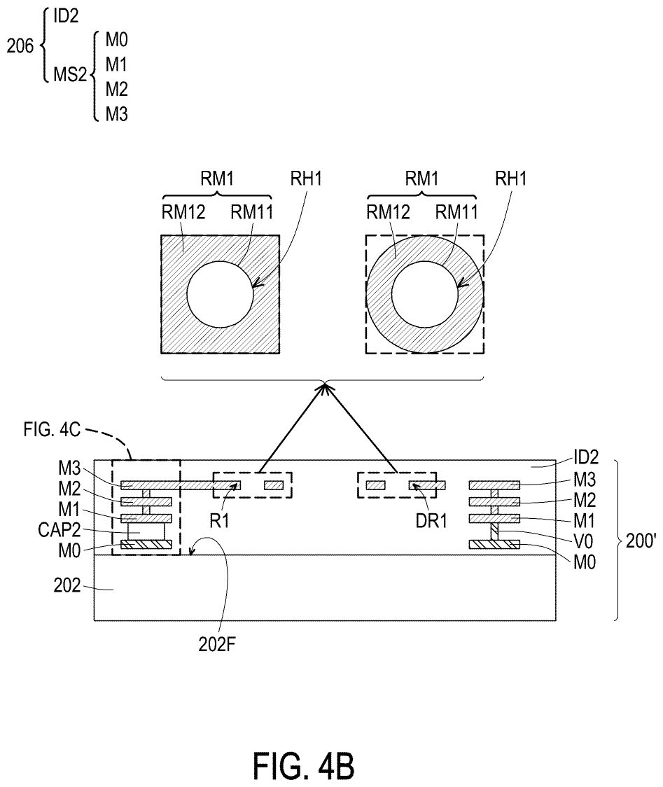

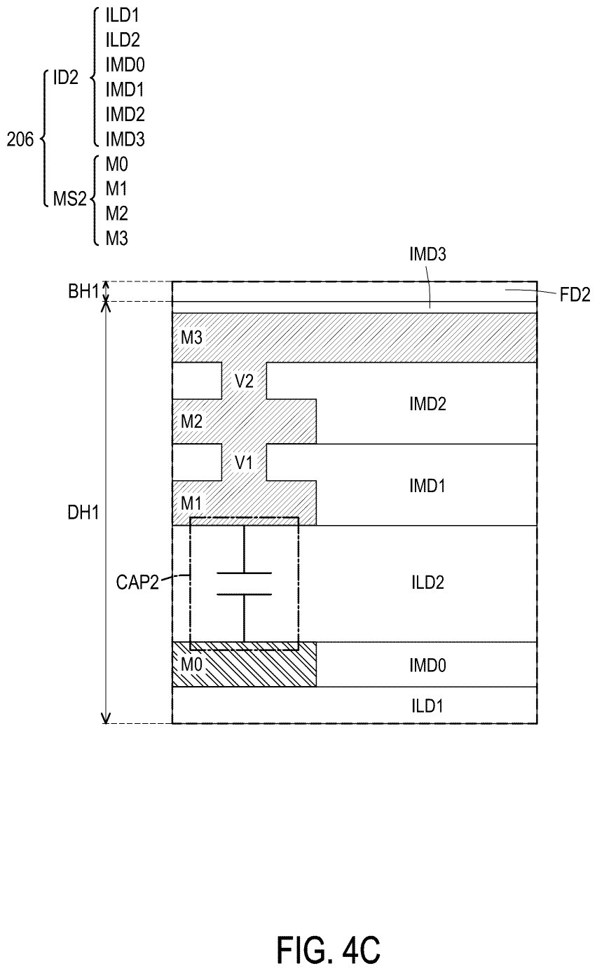

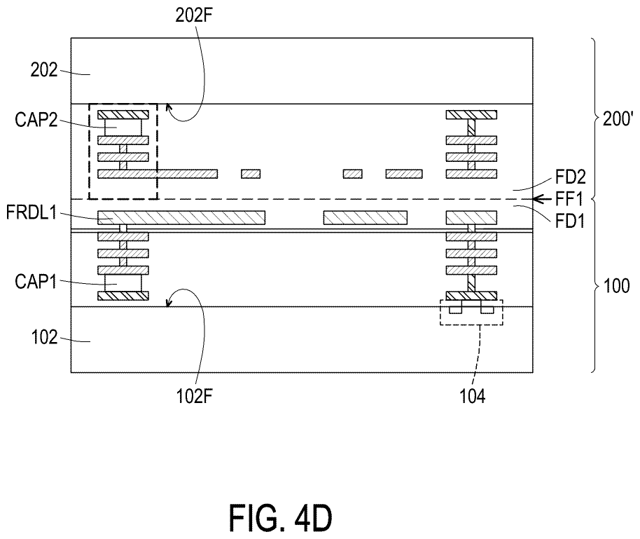

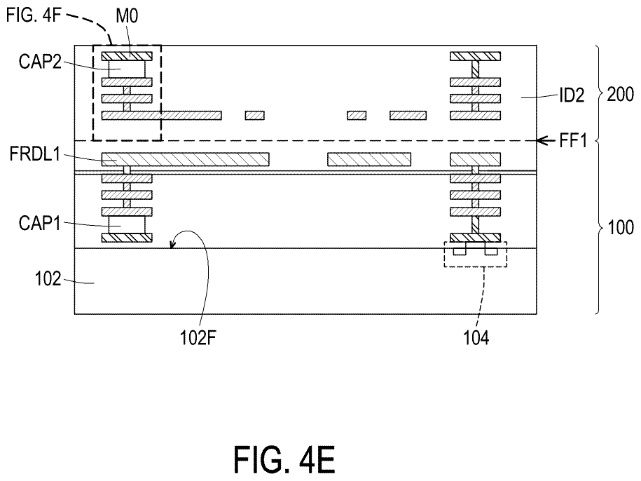

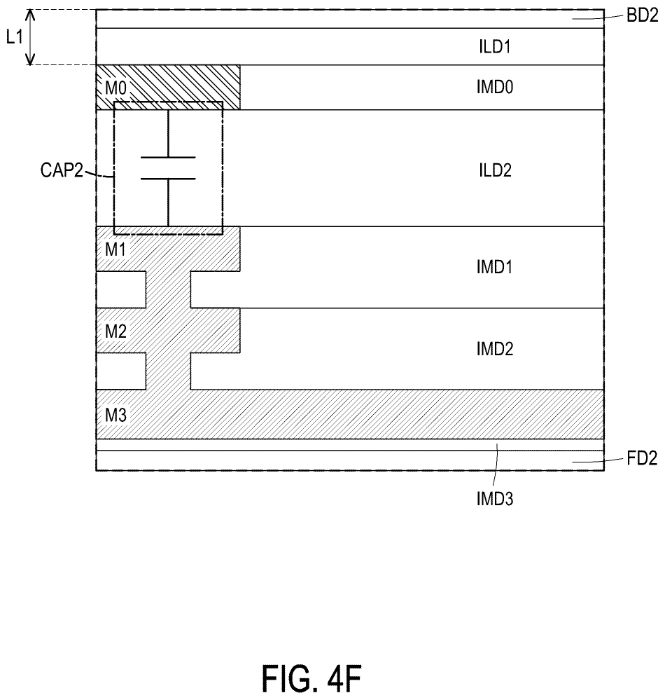

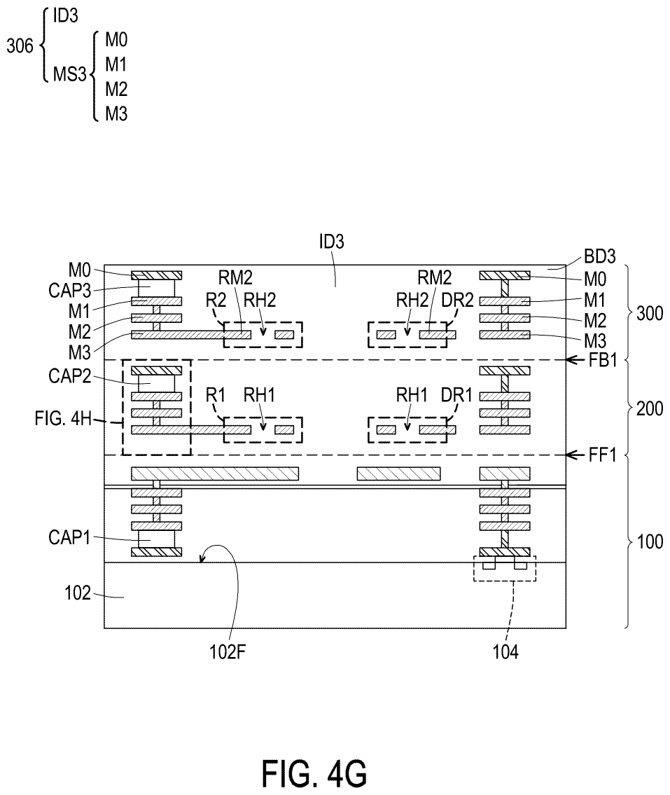

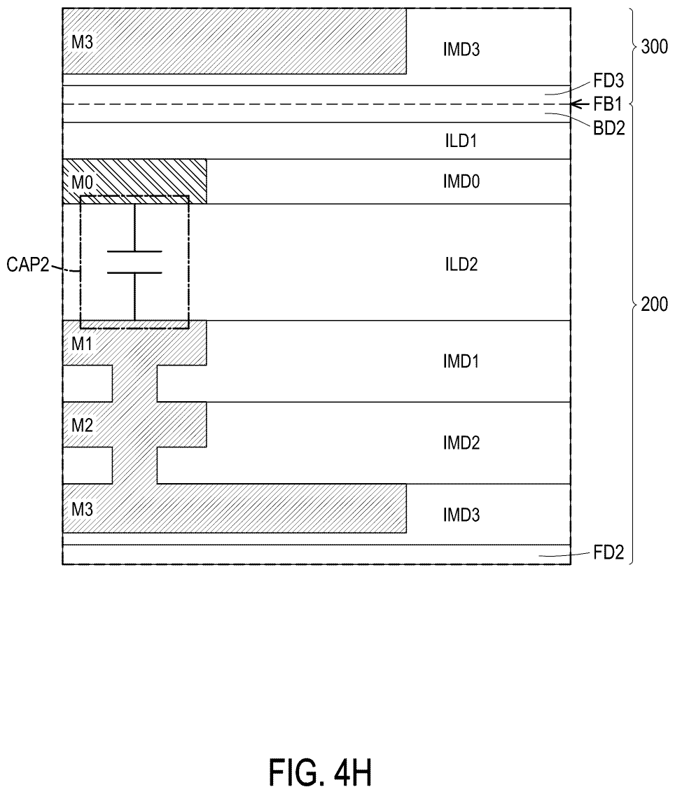

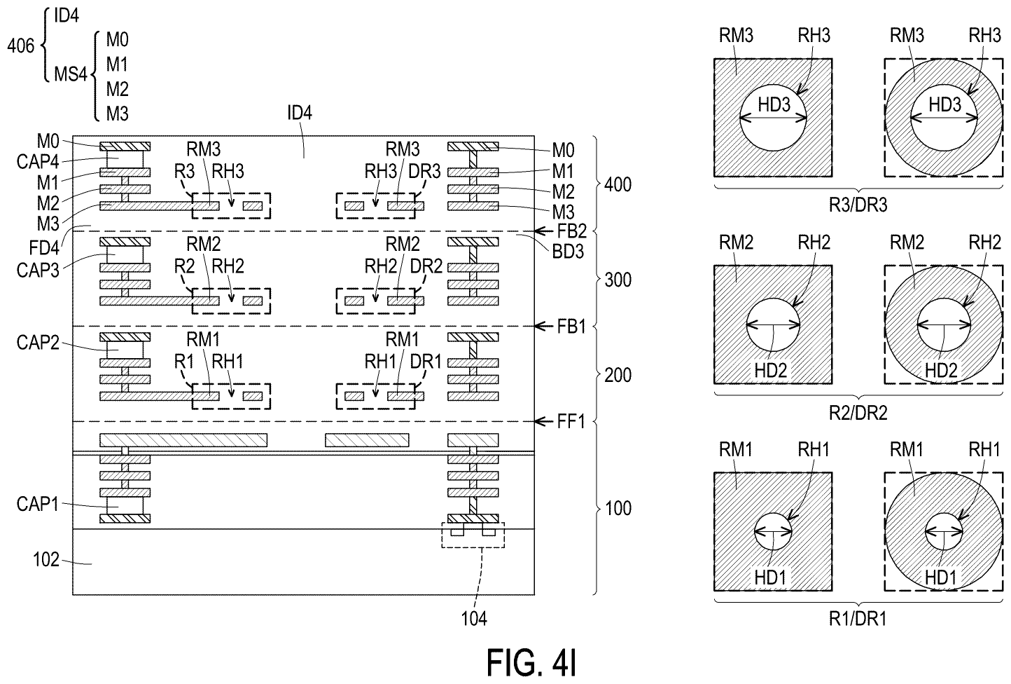

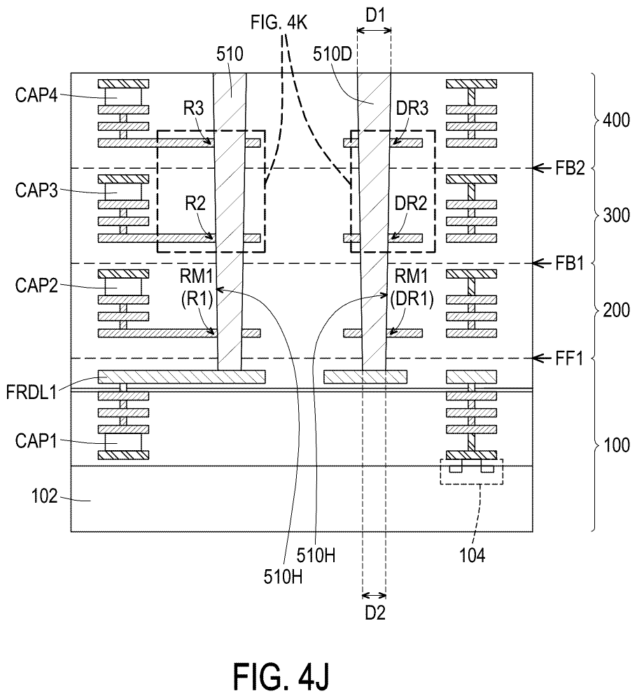

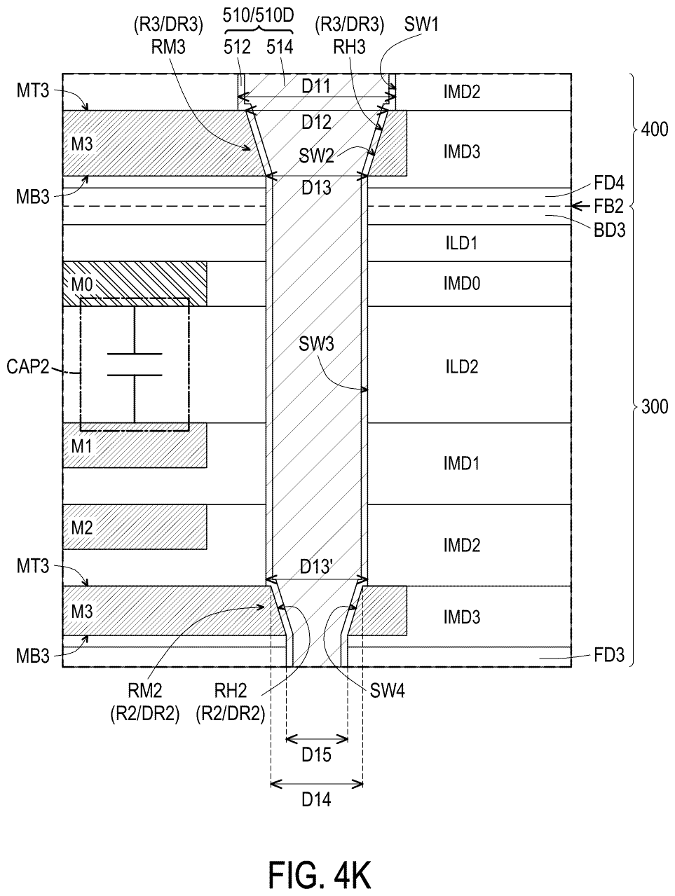

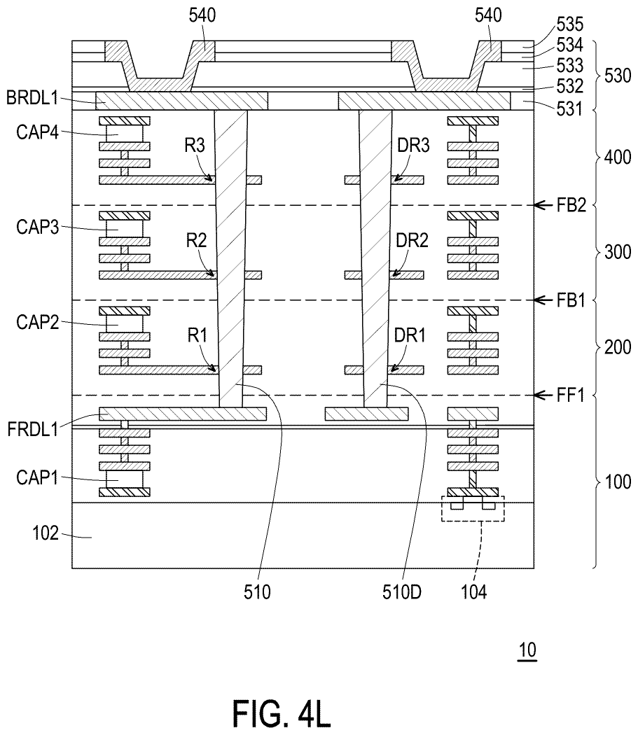

Still referring to FIG. 1, the bottom tier 100 may be much thicker than the overlying tiers (e.g., 200, 300, and 400) alone or in combination. For example, the thickness 100H of the bottom tier 100 is about 760 micrometers, while the thickness 200H of the first tier 200, the thickness 300H of the second tier 300, and the thickness 400H of the third tier 400 may be about 6 micrometers. As compared to the comparative embodiment where the overlying tier having a substrate, the overlying tier (e.g., the first tier 200, the second tier 300, and the third tier 400) of the present embodiment may be thinner by about 45.5%. It should be noted that the details of the device package 10 may further be explained in accompanying with FIGS. 4A-4H.

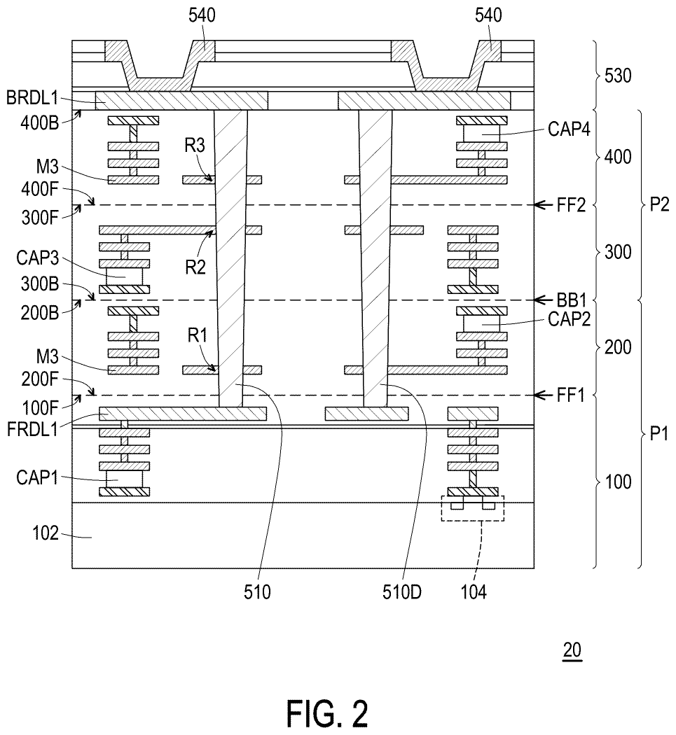

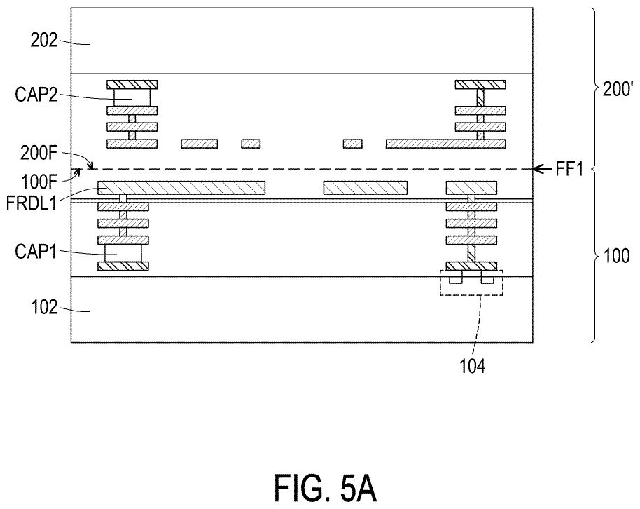

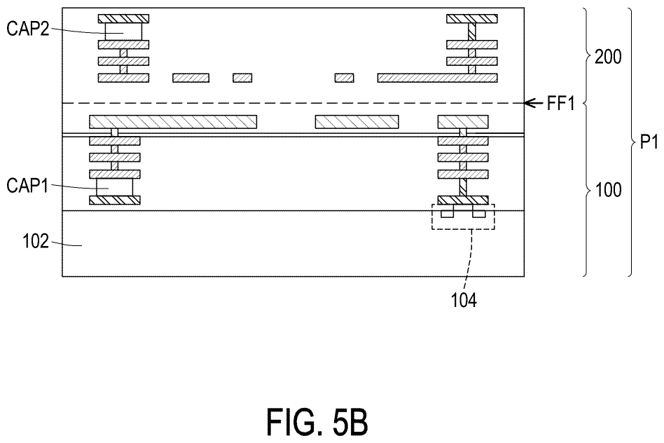

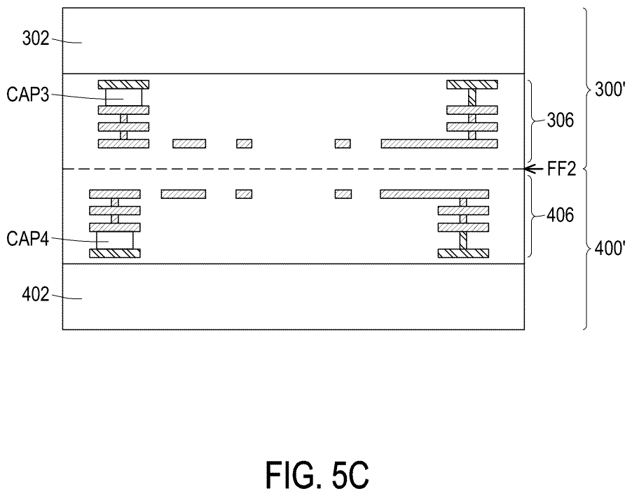

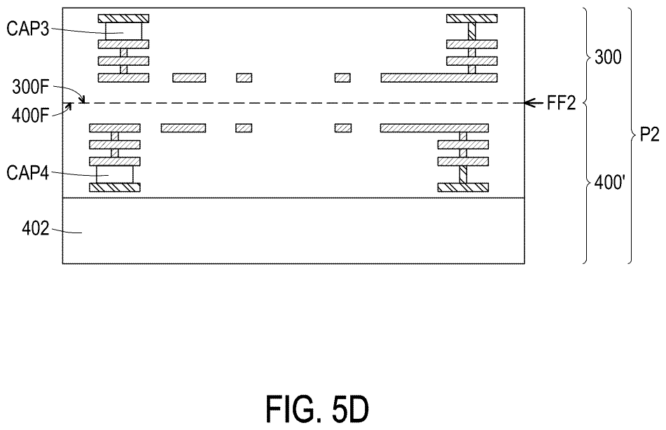

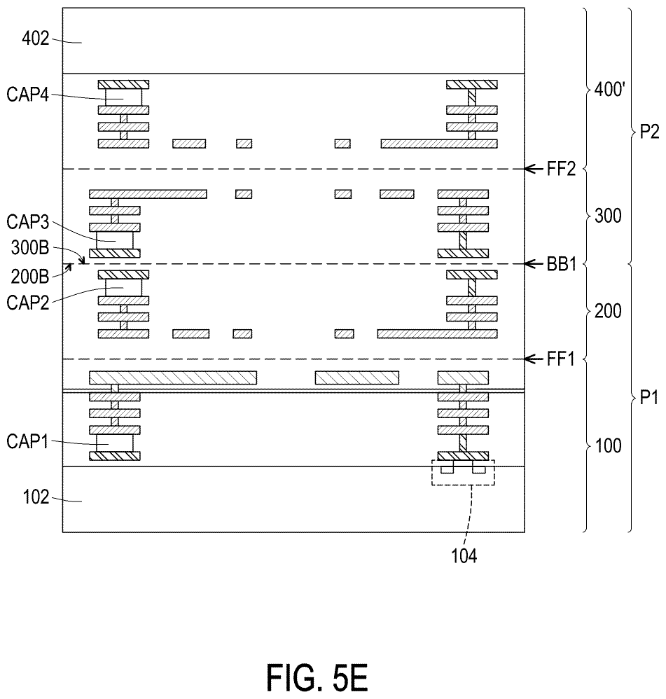

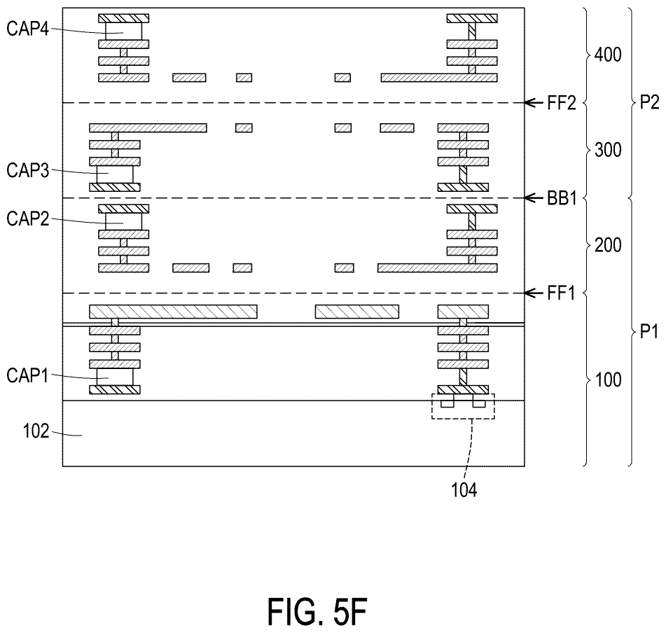

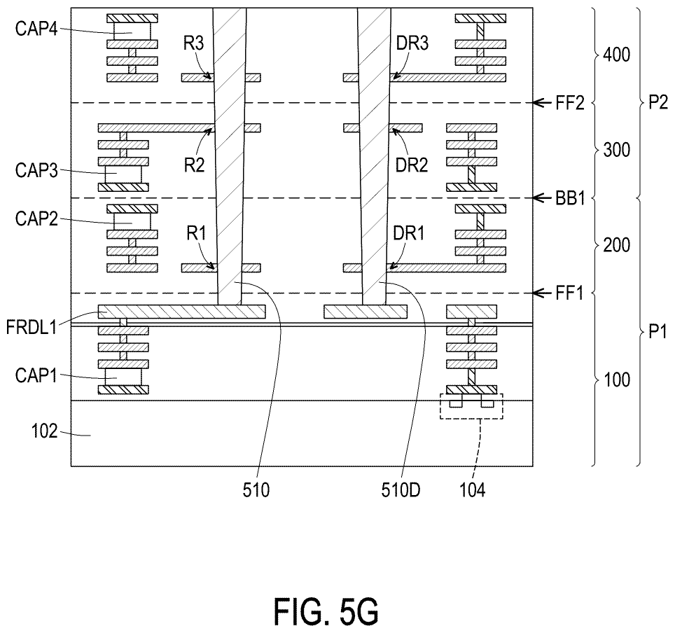

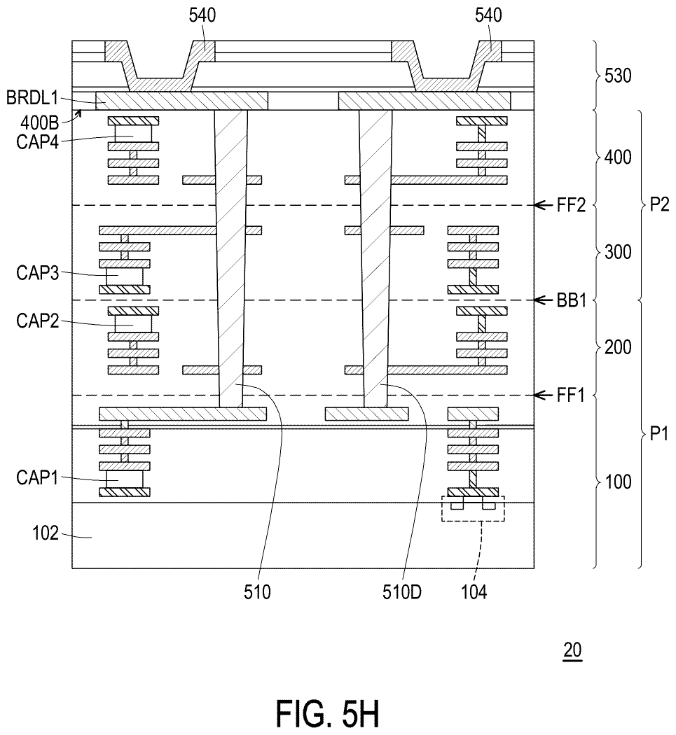

Referring to FIG. 2 and FIG. 1, a device package 20 is similar to the device package 10, except for the configuration of the second tier 300. For example, the back side 300B of the second tier 300 is bonded to the back side 200B of the first tier 200, while the front side 300F of the second tier 300 is bonded to the front side 400F of the third tier 400. A back-to-back bonding interface BB1 is thus formed between the second tier 300 and the first tier 200, and a front-to-front bonding interface FF2 is thus formed between the second tier 300 and the third tier 400. The second tier 300 and the first tier 200 are bonded in a back-to-back configuration, and the second tier 300 and the third tier 400 are bonded in a front-to-front configuration. In the back-to-back configuration, both of the metal layers M3 in the second tier 300 and the first tier 200 may be distal to the back-to-back bonding interface BB1. In the front-to-front configuration, both of the metal layers M3 in the third tier 400 and the second tier 300 may be proximal to the front-to-front bonding interface FF2. For example, the bonding interfaces (e.g., BB1 and FF2) involve dielectric-to-dielectric (e.g., oxide-to-oxide) bonding. The bottom tier 100 and the first tier 200 may be collectively viewed as a first bonding pair P1, and the second tier 300 and the third tier 400 may be collectively viewed as a second bonding pair P2 bonded to the first bonding pair P1. The details of the device package 20 may further be explained in accompanying with FIGS. 5A-5H.

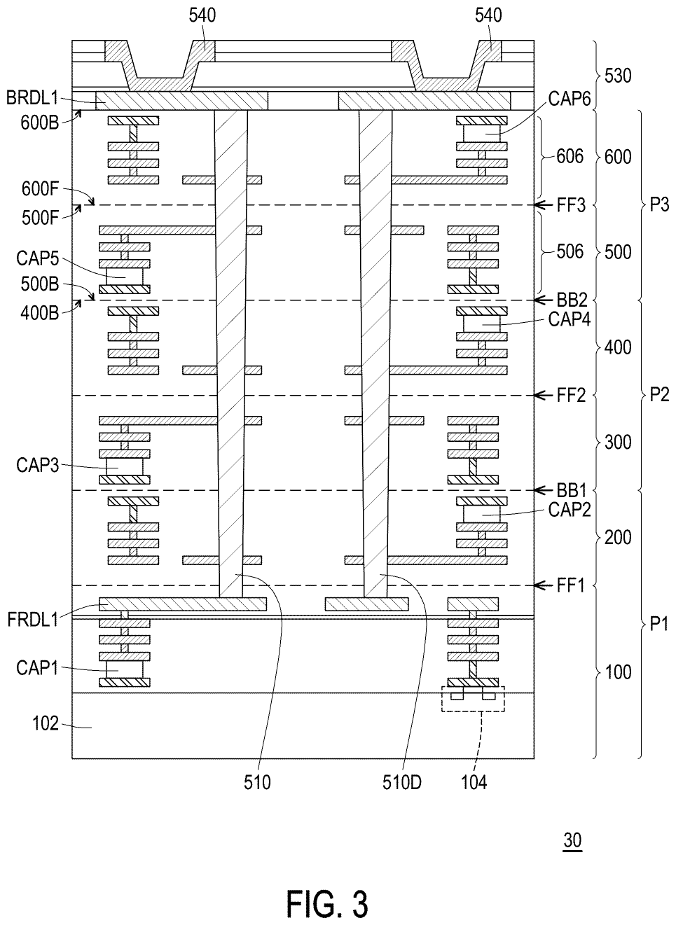

Referring to FIG. 3 and FIG. 2, a device package 30 is similar to the device package 20, except that the device package 30 further includes a third bonding pair P3 stacked upon and bonded to the second bonding pair P2. For example, the third bonding pair P3 includes a fourth tier 500 bonded to the third tier 400 and a fifth tier 600 bonded to the fourth tier 500. A back-to-back bonding interface BB2 may be formed by bonding the back side 500B of the fourth tier 500 to the back side 400B of the third tier 400. A front-to-front bonding interface FF3 may be formed by bonding the front side 600F of the fifth tier 600 to the front side 500F of the fourth tier 500. The fifth tier 600 and the fourth tier 500 are bonded in a front-to-front configuration. For example, the bonding interfaces BB2 and FF3 involve dielectric-to-dielectric (e.g., oxide-to-oxide) bonding. The fourth tier 500 and the fifth tier 600 are similar to the second tier 300 and the third tier 400, respectively. For example, the fourth tier 500 includes a fourth interconnect structure 506 and one or more fifth device(s) CAP5 formed therein. The fifth tier 600 includes a fifth interconnect structure 606 and one or more sixth device(s) CAP6 formed therein.

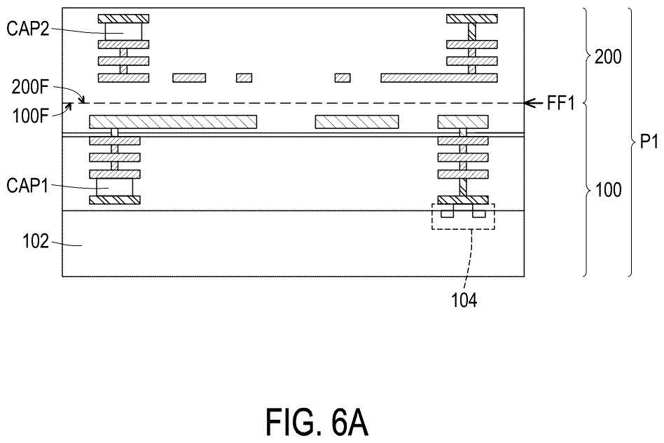

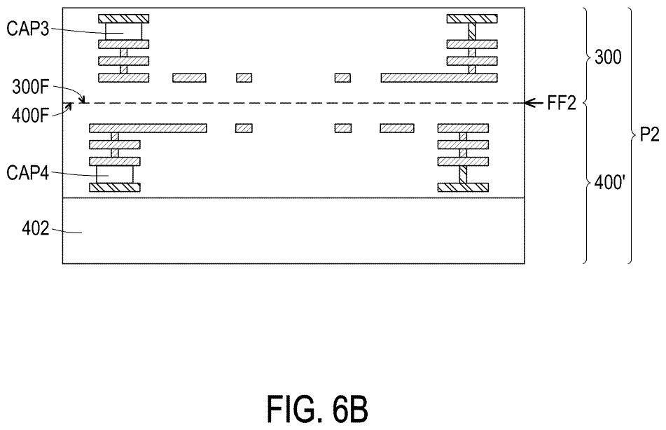

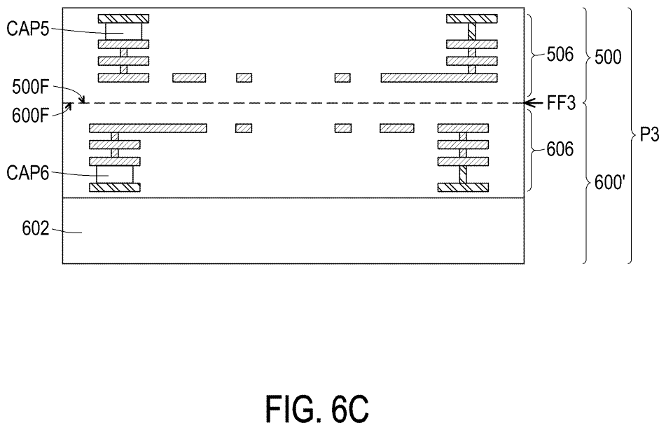

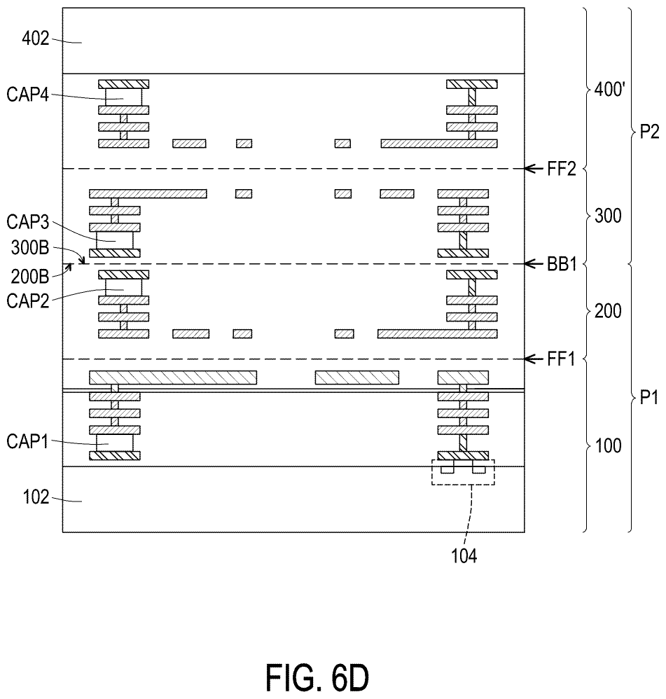

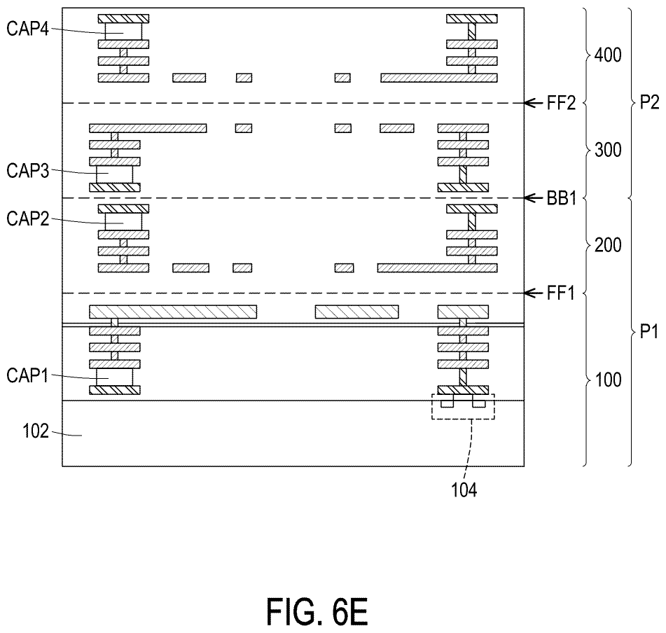

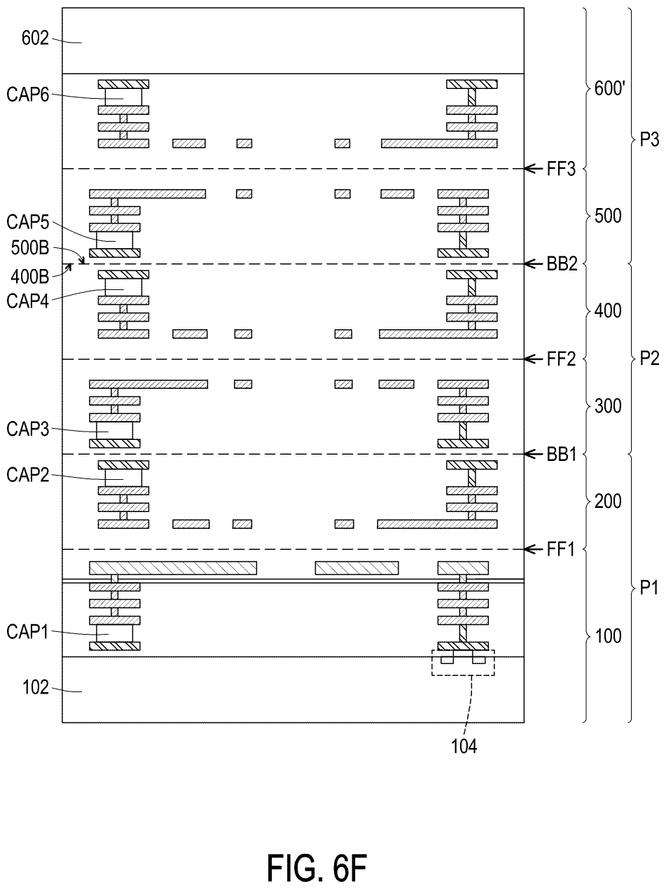

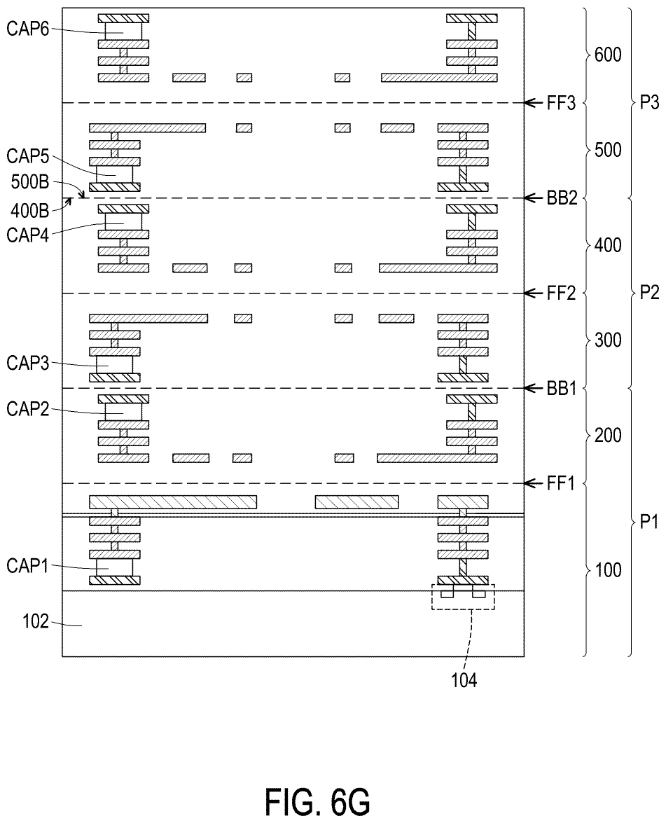

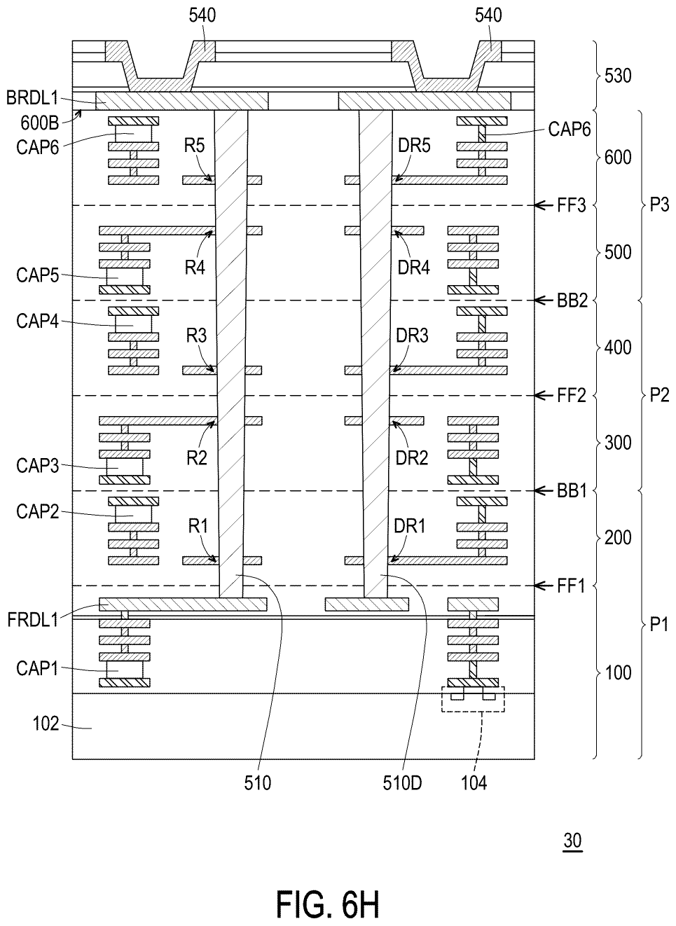

The device package 30 may include one or more TDV(s) (e.g., 510 and 510D) and each TDV (510 or 510D) may penetrate through the fifth tier 600, the fourth tier 500, third tier 400, the second tier 300, and the first tier 200, and land on the bottom tier 100. The device package 30 may include the backside redistribution layer BRDL1 formed on the back side 600B of the fifth tier 600 and connected to the TDVs 510 (and 510D, if desired). The passivation structure 530 of the device package 30 may be formed on the back side 600B of the fifth tier 600 and bury the backside redistribution layer BRDL1 therein. In some embodiments, the device package 30 includes the UBM pads 540 formed on the backside redistribution layer BRDL1 and partially exposed by the passivation structure 530. The details of the device package 30 may further be explained in accompanying with FIGS. 6A-6H.

FIGS. 4A, 4B, 4D-4E, 4G, 4I-4J, and 4L illustrate schematic cross-sectional views of a method for forming a device package and FIGS. 4C, 4F, 4H, and 4K illustrate schematic and exemplary expanded views of FIGS. 4B, 4E, 4G, and 4J, respectively, according to some embodiments of the present disclosure. In manufacturing the device package 10 shown in FIG. 1 may refer to FIGS. 4A-4L. Referring to FIGS. 4A-4C, a bottom tier 100 and a first tier 200′ are respectively provided. As shown in FIG. 4A, the bottom tier 100 includes the bottom substrate 102 and one or more bottom device(s) 104 formed in/on the front side 102F of the bottom substrate 102. In some embodiments, the bottom substrate 102 may include silicon substrate, Gallium-Arsenide substrate, glass substrate, Silicon-On-Insulator (SOI) substrate, or other suitable materials. FIG. 4A shows an example of a transistor (e.g., a complementary metal-oxide semiconductor transistor or the like) as the bottom device 104; however, in other embodiments, the bottom device 104 may be or include other types of active and/or passive devices. For example, the bottom device 104 is formed by FEOL processes and may be referred to as FEOL devices.

The bottom tier 100 includes the bottom interconnect structure 106 formed over the front side 102F of the bottom substrate 102 and overlying the bottom device 104. For example, the bottom interconnect structure 106 includes a dielectric structure ID1 and a metallization structure MS1 formed in the dielectric structure ID1. The dielectric structure ID1 may include interlayer dielectric (ILD) layers and inter-metal dielectric (IMD) layers. The metallization structure MS1 may include a plurality of metal layers (e.g., M0, M1, M2, and M3) electrically coupled by metal vias. In some embodiments, the metal layer M0 and the metal via connected to the metal layer M0 are made of tungsten (W), while the metal layers (e.g., M1, M2, and M3) overlying the metal layer M0 and the metal vias connected to the metal layers (e.g., M1, M2, and M3) are made of copper (Cu), aluminum (Al), or the like. It should be noted that the configuration of the bottom interconnect structure 106 shown herein is merely exemplary, and the number of metal layers, ILD layers, and IMD layers is not limited in the disclosure.

With continued reference to FIG. 4A, one or more first device(s) CAP1 may be formed in the bottom interconnect structure 106. For example, the first device CAP1 is formed in the dielectric structure ID1 and coupled to the metal layers (M0 and M1). In some embodiments where the first device CAP1 is a capacitor, the metal layer M0 serves as a bottom electrode of the capacitor and the metal layer M1 serves as a top electrode of the capacitor. However, the first device CAP1 may be any type of devices formed within the Back-End-of-Line (BEOL) metal layers without the requirement of the bottom substrate 102, depending on product requirements. The first device CAP1 may be formed by BEOL processes and may be referred to as BEOL devices. In some embodiments, the first device CAP1 may be electrically coupled to the bottom device 104 through the metallization structure MS1. In some embodiments, the bottom tier 100 may include the bottom device 104 without the requirement to additionally form the first device CAP1 in the bottom tier 100. In other words, the bottom tier 100 may include the bottom device 104 without the first device CAP1.

The bottom tier 100 includes the front-side redistribution layer FRDL1 formed over and electrically coupled to the metallization structure MS1. The front-side redistribution layer FRDL1 may be formed within a dielectric structure DL1. In some embodiments, the dielectric structure DL1 includes an etch stop layer ESL1 overlying the dielectric structure ID1 and separating the underlying dielectric structure ID1 from the overlying dielectric layers. The conductive vias of the front-side redistribution layer FRDL1 may penetrate through the etch stop layer ESL1 to land on the top of the metallization structure MS1 (e.g., M3). In some embodiments, the dielectric structure DL1 includes a front-side bonding dielectric layer FD1 on the top of the dielectric structure DL1 for facilitating the subsequently-performed bonding process.

With continued reference to FIGS. 4B-4C, the first tier 200′ includes a first substrate 202 and the first interconnect structure 206 formed over the front side 202F of the first substrate 202. The first interconnect structure 206 may be similar to the bottom interconnect structure 106. For example, the first interconnect structure 206 includes a dielectric structure ID2 and a metallization structure MS2 formed in the dielectric structure ID2. The dielectric structure ID2 may include ILD layers (e.g., ILD1 and ILD2) and IMD layers (e.g., IMD0, IMD1, IMD2, and IMD3), as shown in the exemplary expanded view of FIG. 4C. For example, the ILD layer ILD1 is between the IMD layer IMD0 and the first substrate 202. In some embodiments, the ILD layer ILD1 is a device-free layer. In some embodiments, the ILD layer ILD1 is used as a stopping layer during the subsequently-performed removal process of the first substrate 202 (see FIG. 4E). In some embodiments, the dielectric structure ID2 includes a front-side bonding dielectric layer FD2 on the top of the dielectric structure ID2 for facilitating the subsequently-performed bonding process. The front-side bonding dielectric layer FD2 may be thinner than the dielectric structure ID2. For example, the thickness BH1 of the front-side bonding dielectric layer FD2 is about 0.5 micrometers, while the overall thickness DH1 of the dielectric structure ID2 is about 5 micrometers. In some embodiments, the front side bonding dielectric layers FD1 and FD2 may be or include an oxide, silicon nitride (SiN), silicon oxynitride (SiON), silicon carbonitride (SiCN), and/or any suitable bonding dielectric material(s).

With continued reference to FIGS. 4B-4C, the metallization structure MS2 of the first tier 200′ may include a plurality of metal layers (e.g., M0, M1, M2, and M3) electrically coupled by metal vias (e.g., V0, V1, and V2). In some embodiments, the metal layer M0 are made of W, while the overlying metal layers (e.g., M1, M2, and M3) are made of Al, alloy thereof, or the like. In some embodiments, the metal layer M0 is embedded in the IMD layer IMD0, the metal layer M1 and the metal via V1 are embedded in the IMD layer IMD1, the metal layer M2 and the metal via V2 are embedded in the IMD layer IMD2, the metal layer M3 is embedded in the IMD layer IMD3, and the front-side bonding dielectric layer FD2 overlies the IMD layer IMD3. It should be noted that the configuration of the first interconnect structure 206 shown herein is merely exemplary, and the number of metal layers, ILD layers, and IMD layers is not limited in the disclosure.

In some embodiments, the top of the metallization structure MS2 (e.g., the metal layer M3) includes one or more connection branch(es) (e.g., R1 and DR1). The connection branches (e.g., R1 and DR1) may be made of Al, alloy thereof, or other suitable metallic material(s). In some embodiments, the material of the connection branches can be facilitated the subsequently-performed dry etching process and generate fewer by-products during the etching process. In some embodiments, the material of the connection branches is different from the material of the through tier vias which will be formed in following steps. In FIG. 4B, a schematic top view of the connection branch (e.g., R1 and DR1) in the metal layer M3 framed by the lower dashed squares is shown at the upper part of FIG. 4B. For example, the respective connection branch (e.g., R1 or DR1) includes a metal segment RM1 encircling a hollow region RH1. The metal segment RM1 may include a ring RM11 and an extension RM12 connecting the ring RM11 to other portion of the metal layer M3, where the hollow region RH1 is defined by the ring RM11. At this stage, the hollow region RH1 is filled with the dielectric material(s) of the dielectric structure ID2. The metal segment RM1 may have a square (or a rectangular) top-view shape (similar to the left-hand side figure in the upper part of FIG. 4B), a circular top-view shape (similar to the right-hand side figure in the upper part of FIG. 4B), or any suitable top-view shape, depending on circuit and product requirements. In some embodiments, the metal segment RM1 of the connection branch R1 is electrically connected to other metal layers (e.g., M2, M1, and/or M0). In some embodiments, the metal segment RM1 of the additional connection branch DR1 is electrically isolated from other metal layers and may be referred to as additional metal segment. The connection branch DR1 may also be viewed as an additional connection branch. For example, the metal segment RM1 of the additional connection branch DR1 may be used for etching profile tuning patterns for additional through tier via 510D in subsequent processes and improve the profile uniformity between the through tier via 510 and the additional through tier via 510D.

With continued reference to FIGS. 4B-4C, one or more second device(s) CAP2 is formed in the first interconnect structure 206. For example, the second device CAP2 is embedded in the ILD layer ILD2 of the dielectric structure ID2 and physically and electrically coupled to the metal layers (M0 and M1). In some embodiments, the ILD layer ILD2 is thicker than other IMD and ILD layers (e.g., ILD1, IMD0, IMD1, IMD2, and IMD3) due to the space requirement for formation of the second device CAP2. In some embodiments, the thickness of the ILD layer ILD2 is in a range between about 1 to 3 micrometers. In some embodiments where the second device CAP2 is a capacitor, the metal layer M0 serves as a bottom electrode of the capacitor and the metal layer M1 serves as a top electrode of the capacitor. In some embodiments, the second device CAP2 is a capacitor and may comprise a plurality of first conductive films and second conductive film. The first conductive films electrically coupled to the top electrode (e.g., the metal layer M1) and extend toward the bottom electrode (e.g., the metal layer M0). The second conductive films electrically couple to the bottom electrode and extend toward the top electrode. The first conductive films are interlaced with the second conductive films. However, the second device CAP2 may be any type of BEOL devices (e.g., inductors or the like), depending on product requirements. The metal segment RM1 of the connection branch R1 may be electrically coupled to the second device CAP2, while the additional metal segment RM1 of the connection branch DR1 is electrically isolated from the second device CAP2.

Referring to FIG. 4D and FIGS. 4A-4C, the first tier 200′ is bonded to the bottom tier 100. For example, the front-side bonding dielectric layer FD2 of the first tier 200′ is bonded to the front-side bonding dielectric layer FD1 of the bottom tier 100 through fusion bonding (e.g., oxide-to-oxide bonding or the like). A bonding interface FF1 is then formed between the bottom tier 100 and the first tier 200′. The front side 102F of the bottom substrate 102 faces the front side 202F of the first substrate 202, and the bonding interface FF1 may be referred to as a front-to-front interface given its placement in the bonded structure. In some embodiments where the bottom tier 100 and the first tier 200′ are provided in wafer form, a wafer-to-wafer bonding process is performed to bond the first tier 200′ to the bottom tier 100. In some embodiments where the bottom tier 100 is provided in wafer form and the first tier 200′ is provided in die form, a die-to-wafer bonding process is performed to bond the first tier 200′ to the bottom tier 100.

Referring to FIGS. 4E-4F and FIG. 4D, the first substrate 202 of the first tier 200′ may be removed through, e.g., chemical mechanical polishing (CMP), dry etching, wet etching, a combination thereof, or any suitable removal process, thereby forming the first tier 200 bonded to the bottom tier 100. In some embodiments, the first substrate 202 is fully removed, the dielectric structure ID2 (e.g., the ILD layer ILD1) is exposed after removing the first substrate 202, and the metal layer M0 connected to the second device CAP2 remains embedded in the dielectric structure ID2. In some embodiments, the first substrate 202 of the first tier 200′ may be removed through wet etching and the wet etching stop while the dielectric structure ID2 is exposed. The removal process through wet etching provides lower cost than using chemical mechanical polishing. In some embodiments, after the removal of the first substrate 202, a backside bonding dielectric layer BD2 is formed on the exposed dielectric structure ID2 (e.g., the ILD layer ILD1) for further bonding process. The backside bonding dielectric layer BD2 may be or include an oxide, silicon nitride (SiN), silicon oxynitride (SiON), silicon carbonitride (SiCN), and/or any suitable bonding dielectric material(s). As shown in the exemplary expanded view of FIG. 4F, the ILD layer ILD1 is between the IMD layer IMD0 and the backside bonding dielectric layer BD2 after removing the first substrate 202. The backside bonding dielectric layer BD2 may be directly connected to the ILD layer ILD1 of the dielectric structure ID2. In some embodiments, a vertical distance L1 between the outermost surface of the backside bonding dielectric layer BD2 (or the bonding interface FB1 described in FIG. 4G) and the surface of the metal layer M0 interfaced with the ILD layer ILD1 is less than 2 micrometers. The thinner height is achieved resulting from the fully removal of the first substrate 202.

Referring to FIGS. 4G-4H and FIGS. 4E-4F, a second tier 300 is bonded to the first tier 200. The second tier 300 is similar to the first tier 200, and thus the detailed descriptions of the second tier 300 are not repeated herein for the sake of brevity. For example, the second tier 300 includes the second interconnect structure 306, and the second interconnect structure 306 includes a dielectric structure ID3 and a metallization structure MS3 formed in the dielectric structure ID3. In some embodiments, the dielectric structure ID3 includes a front-side bonding dielectric layer FD3 on the top of the dielectric structure ID3 and bonded to the backside bonding dielectric layer BD2 of the first tier 200. The metallization structure MS3 may include a plurality of metal layers (e.g., M0, M1, M2, and M3) electrically coupled by metal vias. It should be noted that the configuration of the second interconnect structure 306 shown herein is merely exemplary, and the number of metal layers, ILD layers, and IMD layers is not limited in the disclosure.

In some embodiments, the metallization structure MS3 of the second tier 300 includes one or more connection branch(es) (e.g., R2 and DR2) formed in the metal layer M3. The connection branches R2 and DR2 are respectively similar to the connection branches R1 and DR1 described in FIG. 4B, except that the hollow region RH2 of the connection branch R2/DR2 is greater than the hollow region RH1 of the connection branch R1/DR1. The details thereof will be described in accompanying with FIG. 4I. In some embodiments, the connection branch R2 of the metallization structure MS3 of the second tier 300 is directly over the connection branch R1 of the first tier 200. For example, the hollow region RH2 of the second tier 300 is substantially and vertically aligned with the hollow region RH1 of the first tier 200. The additional connection branch DR2 of the metallization structure MS3 of the second tier 300 may be directly over the additional connection branch DR1 of the first tier 200. For example, the hollow region RH2 of the second tier 300 is substantially and vertically aligned with the hollow region RH1 of the first tier 200. The second tier 300 includes one or more third device(s) CAP3 formed in the second interconnect structure 306. For example, the third device CAP3 is embedded in the dielectric structure ID3 and physically and electrically coupled to the metal layers (M0 and M1). The third device CAP3 of the second tier 300 may be similar to the second device CAP2 of the first tier 200 described in FIG. 4B. The metal segment RM2 of the connection branch R2 may be electrically coupled to the third device CAP3, while the additional metal segment RM2 of the additional connection branch DR2 is electrically isolated from the third device CAP3.

With continued reference to FIGS. 4G-4H, in some embodiments, the original second tier (not shown), similar to the first tier 200′ described in FIG. 4B, is provided, and then the front-side bonding dielectric layer FD3 of the original second tier is bonded to the backside bonding dielectric layer BD2 of the first tier 200. Subsequently, the substrate of the original second tier may be removed through the process similar to the removal process of the first substrate 202 described in the FIG. 4E. The second tier 300 is thus formed. The backside bonding dielectric layer BD3 of the second tier 300 is optionally formed on the exposed dielectric structure ID3 for further bonding process (if needed). In some embodiments, referring to the exemplary expanded view shown in FIG. 4H, a bonding interface FB1 is formed between the first tier 200 and the second tier 300. The front side of the second tier 300 faces the back side of the first tier 200, and the bonding interface FB1 may be referred to as a front-to-back interface given its placement in the bonded structure.

Referring to FIG. 4I and FIGS. 4G-4H, a third tier 400 is bonded to the second tier 300. The third tier 400 is similar to the first tier 200, and thus the detailed descriptions of the third tier 400 are not repeated herein for the sake of brevity. For example, the third tier 400 includes a third interconnect structure 406, and the third interconnect structure 406 includes a dielectric structure ID4 and a metallization structure MS4 formed in the dielectric structure ID4. In some embodiments, the dielectric structure ID4 includes a front-side bonding dielectric layer FD4 on the top of the dielectric structure ID4 and bonded to the backside bonding dielectric layer BD3 of the second tier 300. The metallization structure MS4 may include a plurality of metal layers (e.g., M0, M1, M2, and M3) electrically coupled by metal vias. It should be noted that the configuration of the third interconnect structure 406 shown herein is merely exemplary, and the number of metal layers, ILD layers, and IMD layers is not limited in the disclosure.

In some embodiments, the metallization structure MS4 of the third tier 400 includes one or more connection branch(es) (e.g., R3 and DR3) formed in the metal layer M3. The connection branches R3 and DR3 are respectively similar to the connection branches R1 and DR1 described in FIG. 4B. In some embodiments, the connection branch R3 of the third tier 400 is directly over the connection branch R2 of the second tier 300 and the connection branch R1 of the first tier 200. For example, the hollow region RH3 of the connection branch R3 of the third tier 400 is substantially and vertically aligned with the hollow region RH2 of the connection branch R2 of the second tier 300 and the hollow region RH1 of the connection branch R1 of the first tier 200. The additional connection branch DR3 of the third tier 400 is directly over the additional connection branch DR2 of the second tier 300 and the additional connection branch DR1 of the first tier 200. For example, the hollow region RH3 of the third tier 400 is substantially and vertically aligned with the hollow region RH2 of the second tier 300 and the hollow region RH1 of the first tier 200.

In FIG. 4I, schematic top views of the connection branches (R1-R3 and DR1-DR3) circled by the dashed squares at the left-hand side of FIG. 4I are shown at the right-hand side of FIG. 4I. The difference among the connection branches R1-R3 (or DR1-DR3) lies in that the width (or the diameter) HD3 of the hollow region RH3 in the third tier 400 is greater than the width (or the diameter) HD2 of the hollow region RH2 in the second tier 300, and the width (or the diameter) HD2 of the hollow region RH2 in the second tier 300 is greater than the width (or the diameter) HD1 of the hollow region RH1 in the first tier 200.

Still referring to FIG. 4I, the third tier 400 includes one or more fourth device(s) CAP4 formed in the third interconnect structure 406. For example, the fourth device CAP4 is embedded in the dielectric structure ID4 and physically and electrically coupled to the metal layers (M0 and M1). The fourth device CAP4 of the third tier 400 may be similar to the second device CAP2 of the first tier 200 described in FIG. 4B. The metal segment RM3 of the connection branch R3 may be electrically coupled to the fourth device CAP4, while the additional metal segment RM3 of the additional connection branch DR3 is electrically isolated from the fourth device CAP4.

With continued reference to FIG. 4I, in some embodiments, the original third tier (not shown), similar to the first tier 200′ described in FIG. 4B, is provided, and then the front-side bonding dielectric layer FD4 of the original third tier is bonded to the backside bonding dielectric layer BD3 of the second tier 300. Subsequently, the substrate of the original third tier may be removed through the process similar to the removal process of the first substrate 202 described in the FIG. 4E. The third tier 400 is thus formed. The backside bonding dielectric layer (not shown) of the third tier 400 may be formed on the exposed dielectric structure ID4 for further bonding process. Alternatively, the backside bonding dielectric layer is omitted. For example, a bonding interface FB2 is formed between the second tier 300 and the third tier 400. The front side of the third tier 400 faces the back side of the second tier 300, and the bonding interface FB2 may be referred to as a front-to-back interface given its placement in the bonded structure.

Referring to FIGS. 4J-4K and FIG. 4I, one or more TDVs (e.g., 510 and 510D) is formed through the third tier 400, the second tier 300, and the first tier 200 and lands on the front-side redistribution layer FRDL1 of the bottom tier 100. For example, the TDVs (510 and 510D) are formed by: removing dielectric materials in the third tier 400, the second tier 300, the first tier 200, and the upper part of the bottom tier 100 so as to form through holes 510H; and forming conductive material(s) in the through holes 510H to form the TDVs (510 and 510D). The through holes 510H may be formed by suitable etching process (e.g., dry etching), and the conductive material(s) may be formed by plating process or suitable deposition process. In some embodiments, the material of the respective TDV (510 or 510D) includes copper (Cu), aluminum (Al), titanium (Ti), titanium nitride (TiN), tantalum (Ta), tantalum nitride (TaN), tungsten (W) or other suitable metallic material(s) which has better filling capability than tungsten (W) and/or lower cost. In some embodiments, referring to the exemplary expanded view shown in FIG. 4K, the respective TDV (510 or 510D) includes a barrier liner 512 and a filled-metal layer 514 overlying the barrier liner 512. For example, the barrier liner 512 is made of TaN and the filled-metal layer 514 is made of Cu.

In some embodiments, during the step of forming the through holes 510H, the dielectric materials in the hollow region RH3 of the connection branches (R3 and DR3), the hollow region RH2 of the connection branches (R2 and DR2), and the hollow region RH1 of the connection branches (R1 and DR1) are at least partially (or fully) removed. The TDVs (510 and 510D) may be in lateral contact with the metal segments of the corresponding connection branches in each tier overlying the bottom tier 100. For example, the TDV 510 is in lateral and electrical contact with the metal segment RM3 of the connection branch R3 in the third tier 400, the metal segment RM2 of the connection branch R2 in the second tier 300, and the metal segment RM1 of the connection branch R1 in the first tier 200. The TDV 510D may be in lateral contact with the metal segment RM3 of the additional connection branch DR3 in the third tier 400, the metal segment RM2 of the additional connection branch DR2 in the second tier 300, and the metal segment RM1 of the additional connection branch DR1 in the first tier 200. The TDV 510D may be viewed as an additional TDV and may be used for dummy patterns to improve the etching or chemical-mechanical polishing uniformity during the formation of the TDV 510. In some embodiments, the additional TDV 510D may be used for electrical/signal routings in the device package, and the TDV 510D may provide direct electrical/signal routing between the bottom tier 100 and the corresponding under-bump metallization pad.

With continued reference to FIGS. 4J-4K, the respective TDV (510 or 510D) may be tapered in a direction from the third tier 400 toward the bottom tier 100. For example, the top width (or diameter) D1 of the respective TDV (510 or 510D) is greater than the bottom width (or diameter) D2 of the respective TDV (510 or 510D). The variation of the critical dimension (CD) of the respective TDV (510 or 510D) may be obtained by the equation: [(D1-D2)/D1]*100%. For example, the variation of the CD of the respective TDV (510 or 510D) is about 48.5%. As compared to the embodiments where the overlying tier having a substrate, the variation of the CD of the respective TDV in the present embodiment is reduced due to the lower TDV etching height.

With continued reference to the exemplary expanded view shown in FIG. 4K, FIG. 4K illustrates the entirety of the second tier 300 and a part of the third tier 400 for explanation. The TDV (510 or 510D) is tapered from the top to the bottom in the third tier 400. For example, the width (or diameter) D11 of the TDV (510 or 510D) is greater than the width (or diameter) D12 of the TDV (510 or 510D) and the width (or diameter) D12 is greater than the width (or diameter) D13 of the TDV (510 or 510D), where the width (or diameter) D12 is measured on the virtual plane coplanar with the top surface MT3 of the metal layer M3 in the third tier 400 and the width (or diameter) D13 is measured on the virtual plane coplanar with the bottom surface MB3 of the metal layer M3 in the third tier 400. In some embodiments, the first tapered profile in the third tier 400 laterally surrounded by the dielectric material (e.g., IMD2) is different from the second profile in the third tier 400 laterally surrounded by the connection branch (R3 or DR3). A slope of the TDV (510 or 510D) extending through the dielectric material (e.g., IMD2) may be a different slope than a slope of the TDV (510 or 510D) extending through the metal segment RM3 of the connection branch (R3 or DR3), in the third tier 400. In some embodiments, during the formation of the TDVs (510 and/or 510D), the metal segments of the connection branches may be partially etched to render the sloped sidewall of the TDVs in the corresponding connection branches. For example, the first sidewall SW1 laterally covered by the IMD layer IMD2 has a greater slope than the second sidewall SW2 laterally covered by the metal segment RM3, in the third tier 400.

Still referring to the exemplary expanded view shown in FIG. 4K, the width (or diameter) D13 of the TDV (510 or 510D) is greater than the width (or diameter) D13′ of the TDV (510 or 510D), where the width (or diameter) D13′ is measured on the virtual plane coplanar with the bottom of the IMD layer IMD2 in the second tier 300. The width (or diameter) D13′ is greater than the width (or diameter) D14 of the TDV (510 or 510D) and the width (or diameter) D14 is greater than the width (or diameter) D15 of the TDV (510 or 510D), where the width (or diameter) D14 is measured on the virtual plane coplanar with the top surface MT3 of the metal layer M3 in the second tier 300 and the width (or diameter) D15 is measured on the virtual plane coplanar with the bottom surface MB3 of the metal layer M3 in the second tier 300. In some embodiments, the third tapered profile laterally surrounded by the dielectric materials (e.g., FB4, BB3, ILD1, IMD0, ILD2, IMD1, and IMD2) is different from the fourth profile laterally surrounded by the connection branch (R2 or DR2) in the second tier 300. The TDV (510 or 510D) extending through the dielectric materials (e.g., FB4, BB3, ILD1, IMD0, ILD2, IMD1, and IMD2) may have a different slope than a slope of the TDV (510 or 510D) extending through the metal segment RM2 of the connection branch (R2 or DR2). For example, the third sidewall SW3 laterally covered by the dielectric materials (e.g., FB4, BB3, ILD1, IMD0, ILD2, IMD1, and IMD2) has a greater slope than the fourth sidewall SW4 laterally covered by the metal segment RM2 in the second tier 300.

The different tapered profiles of the TDV (510 or 510D) are formed by the size shrinkage caused by the high aspect ratio of the section between the widths (D13 and D13′) and the size shrinkage caused by the etchant contacting the connection branches (R1-R3 or DR1-DR3) during the formation of the through holes 510H. For example, the third sidewall SW3 defines the third tapered profile laterally surrounded by the dielectric materials (e.g., FD4, BD3, ILD1, IMD0, ILD2, IMD1, and IMD2), and this section of the TDV (510 or 510D) has the third tapered profile and the aspect ratio defined as the depth divided by the width. The second sidewall SW2 defines the second tapered profile laterally surrounded by the connection branch (R3 or DR3), and the third sidewall SW3 may have a slope steeper than the second sidewall SW2. Similarly, the fourth sidewall SW4 defines the fourth tapered profile laterally surrounded by the connection branches (R2 or DR2), and the third sidewall SW3 may have a slope steeper than the fourth sidewall SW4. In some embodiments, the diameter design of the hallow region in the connection branches and the selection of suitable materials for the connection branches and dielectric layers may be used for confining the etching profile of TDV hole 510H. The different taper shape (e.g., sidewalls SW2/SW4 comparing with sidewall SW3) may provide confinement of the TDV profile during the high-depth and long time period etching process.

Referring to FIG. 4L and FIGS. 4J-4K, a backside redistribution layer BRDL1 is formed on the third tier 400 and connected to the TDVs 510 (and 510D, if desired). For example, the backside redistribution layer BRDL1 is in electrical and physical contact with the TDV 510, the devices (e.g., CAP1-CAP4) in the overlying tiers (e.g., 200, 300, and 400) are electrically coupled to the backside redistribution layer BRDL1 through the TDV 510, and the bottom device 104 is electrically coupled to the backside redistribution layer BRDL1 through the TDV 510 (or TDV 510D, if desired) and the front-side redistribution layer FRDL1. In some embodiments, the additional TDV 510D is physically connected to an additional pattern (not specifically labeled) of the backside redistribution layer BRDL1. In some embodiments, the additional TDV 510D may be used for signal/power routing for the bottom device 104. In some embodiments, the bottom device 104 may be electrically coupled to the passive devices (e.g., CAP1-CAP4, individual or combination) through the front-side redistribution layer FRDL1, the TDV 510, and the backside redistribution layer BRDL1. In some embodiments, the passive devices (e.g., CAP1-CAP4) may be used for power regulating/converting or signal filtration on the bottom device 104. The passivation structure 530 may be formed on the third tier 400 and bury the backside redistribution layer BRDL1 therein. For example, the passivation structure 530 includes one or more sublayers (e.g., 531, 532, 533, 534, and 535) and the backside redistribution layer BRDL1 is embedded in the sublayer 531. In some embodiments, UBM pad(s) 540 is formed on the backside redistribution layer BRDL1 and covered by the passivation structure 530. For example, the UBM pads 540 are laterally covered by the sublayers (e.g., 532, 533, 534, and 535). The UBM pads 540 may be electrically coupled to the TDV 510 through the backside redistribution layer BRDL1. As shown in FIG. 4L, the device package 10 may be obtained.

With continued reference to FIG. 4L, in some embodiments, the bottom tier 100 may simultaneously include the first device CAP1 and the bottom device 104. The bottom tier 100 may be the dynamic-random-access-memory (DRAM), and the bottom device 104 may be the control circuits (e.g., peripheral circuits) signal coupling to the first device CAP1. In some embodiments, the bottom tier 100 may be the processor chip, such as Central-Processing-Unit (CPU), Graphic-Processing-Unit (GPU), Tensor-Processing-Unit (TPU), Neural-Processing-Unit (NPU), or the like. The bottom devices 104 may be the logic transistors in the processor chip, and the first device CAP1 may be the passive device incorporated in the processor chip. In some other embodiments, the bottom tier 100 may include the bottom device 104 without the formation of the first device CAP1. In some other embodiments, the bottom tier 100 may include the first device CAP1 without the formation of the bottom device 104. In that embodiments, the bottom tier 100 may be served as the passive device having similar functions with the other above tiers (e.g., tiers 200/300/400).

FIGS. 5A-5H illustrate schematic cross-sectional views of a method for forming a device package according to some embodiments of the present disclosure. In manufacturing the device package 20 shown in FIG. 2 may refer to FIGS. 5A-5H. Referring to FIG. 5A and FIGS. 4A-4D, the bottom tier 100 and the first tier 200′ are respectively provided and then bonded together. The details of these processes are similar to the process described in FIGS. 4A-4D. The bonding interface FF1 is formed between the first tier 200′ and the bottom tier 100. For example, the first tier 200′ and the bottom tier 100 are bonded in a front-to-front configuration, and the bonding interface FF1 is referred to as the front-to-front bonding interface.

Referring to FIG. 5B, FIG. 5A, and FIG. 4E, the first substrate 202 of the first tier 200′ is removed after bonding the first tier 200′ to the bottom tier 100 to form the first tier 200. The removal process may be similar to as the process described in FIG. 4E. The structure shown in FIG. 5B is viewed as a first pair structure P1.

Referring to FIGS. 5C-5D, the second tier 300′ and the third tier 400′ are respectively provided and then bonded together. At the stage shown in FIG. 5C, the second tier 300′ includes the second substrate 302, the second interconnect structure 306 formed over the second substrate 302, and the third device CAP3 formed in the second interconnect structure 306. Similarly, the third tier 400′ includes the third substrate 402, the third interconnect structure 406 formed over the third substrate 402, and the fourth device CAP4 formed in the third interconnect structure 406. The bonding interface FF2 is formed between the second tier 300′ and the third tier 400′. For example, the front side 300F of the second tier 300′ faces the front side 400F of the third tier 400′, and the bonding interface FF2 is referred to as a front-to-front interface given its placement in the bonded structure. Next, the second substrate 302 of the second tier 300′ is removed to form the second tier 300. The removal process may be similar to as the substrate removal process described in FIG. 4E. The structure shown in FIG. 5D is viewed as a second pair structure P2.

Referring to FIGS. 5E-5F, FIG. 5D, and FIG. 5B, the second pair structure P2 is bonded to the first pair structure P1. For example, the back side 300B of the second tier 300 is bonded to the back side 200B of the first tier 200 to form a bonding interface BB1 through, e.g., fusion bonding or the like. The bonding interface BB1 may be referred to as a back-to-back interface given its placement in the bonded structure. Next, the third substrate 402 of the third tier 400′ may be removed to form the third tier 400 as shown in FIG. 5F. The removing of the third substrate 402 may be similar to the substrate removal process described in FIG. 4E.

Referring to FIG. 5G, FIG. 5F, and FIG. 4G, the TDVs (510 and 510D) are formed in the bonded structure shown in FIG. 5F. The details of the TDVs (510 and 510D) may refer to the TDVs (510 and 510D) described in FIGS. 4J-4K. For example, the TDV 510 passes through the connection branch R3 in the third tier 400, the connection branch R2 in the second tier 300, and the connection branch R1 in the first tier 200, and land on the front-side redistribution layer FRDL1 in the bottom tier 100. The size of the connection branch(es) (e.g., R1-R3 and DR1-DR3) in each of the first tier 200, the second tier 300, and the third tier 400 may be modulated according to the height of the corresponding TDV (510 or 510D). The TDVs (510 and 510D) may be in lateral and electrical contact with the devices (CAP2, CAP3, and CAP4) through the connection branches (e.g., R1-R3) in the first tier 200 through the third tier 400. The TDVs (510 and 510D) are similar to the corresponding elements described in FIG. 4G, and thus the details thereof are not repeated herein.

Referring to FIG. 5H, FIG. 5G, and FIG. 4L, the backside redistribution layer BRDL1 is formed on the back side 400B of the third tier 400 and connected to the TDVs 510 (and 510D, if desired). The passivation structure 530 may be formed on the back side 400B of the third tier 400 and bury the backside redistribution layer BRDL1 therein. In some embodiments, the UBM pads 540 are formed on the backside redistribution layer BRDL1 and partially exposed by the passivation structure 530. The UBM pads 540 may be electrically coupled to the TDV 510 through the backside redistribution layer BRDL1. The backside redistribution layer BRDL1, the passivation structure 530, and the UBM pads 540 are similar to the corresponding elements described in FIG. 4L, and thus the details thereof are not repeated herein. As shown in FIG. 5H, the device package 20 may be obtained.

FIGS. 6A-6H illustrate schematic cross-sectional views of a method for forming a device package according to some embodiments of the present disclosure. In manufacturing the device package 30 shown in FIG. 3 may refer to FIGS. 6A-6H. Referring to FIG. 6A and FIG. 5B, the bottom tier 100 and the first tier 200 are bonded together and the front-to-front bonding interface FF1 is formed therebetween. The structure shown in FIG. 6A is viewed as a first pair structure P1. The detailed descriptions of the first pair structure P1 can refer to the previous embodiments described in FIG. 5B.

Referring to FIG. 6B and FIG. 5D, the second tier 300 and the third tier 400′ are bonded together to form the second pair structure P2, where the front-to-front bonding interface FF2 is formed between the second tier 300 and the third tier 400′. The detailed descriptions of the second pair structure P2 can refer to the previous embodiments described in FIG. 5D.

Referring to FIG. 6C and FIG. 6B, the fourth tier 500 and the fifth tier 600′ are bonded together to form a third pair structure P3. The third pair structure P3 may be similar to the second pair structure P2. For example, the fourth tier 500 includes the fourth interconnect structure 506 and the fifth device CAP5 formed therein. The fifth tier 600′ includes the fifth substrate 602, the fifth interconnect structure 606 formed over the fifth substrate 602, and the sixth device CAP6 formed in the fifth interconnect structure 606. The bonding interface FF3 is formed between the fourth tier 500 and the fifth tier 600′. For example, the front side 500F of the fourth tier 500 faces the front side 600F of the fifth tier 600′, and the bonding interface FF3 is referred to as a front-to-front interface given its placement in the third pair structure P3.

Referring to FIGS. 6D-6E and FIGS. 6A-6B, the second pair structure P2 is bonded to the first pair structure P1. The back side 300B of the second tier 300 may be bonded to the back side 200B of the first tier 200 to form the back-to-back bonding interface BB1. Next, the third substrate 402 of the third tier 400′ may be removed to form the third tier 400 as shown in FIG. 6E. The removing of the third substrate 402 may be similar to the substrate removal process described in FIG. 4E.

Referring to FIGS. 6F-6G and FIG. 6E and FIG. 6C, the third pair structure P3 is bonded to the second pair structure P2. The back side 500B of the fourth tier 500 may be bonded to the back side 400B of the third tier 400 to form the back-to-back bonding interface BB2 through, e.g., fusion bonding or the like. Next, the fifth substrate 602 of the fifth tier 600′ may be removed to form the fifth tier 600 as shown in FIG. 6G. The removing of the fifth substrate 602 may be similar to the substrate removal process described in FIG. 4E.

Referring to FIG. 6H, FIG. 6G, and FIG. 4G, the TDVs (510 and 510D) are formed in the bonded structure shown in FIG. 6G. The details of the TDVs (510 and 510D) may refer to the TDVs (510 and 510D) described in FIGS. 4J-4K and FIGS. 5G-5H. In the illustrated embodiment, the TDV 510 passes through the connection branch R5 in the fifth tier 600, the connection branch R4 in the fourth tier 500, the connection branch R3 in the third tier 400, the connection branch R2 in the second tier 300, and the connection branch R1 in the first tier 200, and land on the front-side redistribution layer FRDL1 in the bottom tier 100. The connection branch R5 in the fifth tier 600 and the connection branch R4 in the fourth tier 500 may be similar to the connection branch R3 in the third tier 400 and the connection branch R2 in the second tier 300, respectively, and thus the detailed descriptions are not repeated herein. The TDV 510 may be in lateral and electrical contact with the devices (CAP2-CAP6) through the connection branches (e.g., R1-R5) in the first tier 200 through the fifth tier 600. The TDV 510 may be electrically coupled to the bottom device 104 and the first device CAP1 in the bottom tier 100 through the front-side redistribution layer FRDL1. The TDV 510 may thus provide the electrical interconnect among the vertical stack of the bottom tier 100 through the fifth tier 600.

In some embodiments, the TDV 510D may also be used for electrical connection for the bottom device 104, the devices CAP1, CAP2, CAP3, CAP4, CAP5, and CAP6. In some other embodiments, the TDV 510D may be used for additional TDV pattern. In that embodiment, the additional TDV 510D may be used to improve the uniformity of the TDV 510 during the fabrication process.

With continued reference to FIG. 6H and FIG. 4L, the backside redistribution layer BRDL1 is formed on the back side 600B of the fifth tier 600 and connected to the TDVs 510 (and 510D, if desired). The passivation structure 530 may be formed on the back side 600B of the fifth tier 600 and bury the backside redistribution layer BRDL1 therein. In some embodiments, the UBM pads 540 are formed on the backside redistribution layer BRDL1 and partially exposed by the passivation structure 530. The UBM pads 540 may be electrically coupled to the TDV 510 through the backside redistribution layer BRDL1. The backside redistribution layer BRDL1, the passivation structure 530, and the UBM pads 540 are similar to the corresponding elements described in FIG. 4L, and thus the details thereof are not repeated herein. As shown in FIG. 6H, the device package 30 may be obtained.

In one exemplary aspect, a device package is provided. The device package includes a first tier, a second tier stacked upon the first tier, and a through tier via unitarily penetrating through the first and second tiers. The first tier includes a first device and a first interconnect structure electrically coupled to the first device, the first interconnect structure includes a first metal layer, and the first metal layer includes a first connection branch. The second tier includes a second device and a second interconnect structure electrically coupled to the second device, the second interconnect structure includes a second metal layer, and the second metal layer includes a second connection branch. The through tier via is electrically coupled to the first and second connection branches.

In another exemplary aspect, a device package is provided. The device package includes a first bonding pair, N second bonding pairs stacked upon the first bonding pair, and a through tier via. The first bonding pair includes a bottom tier and a first tier stacked upon the bottom tier, the bottom tier includes a bottom device and a front-side RDL electrically coupled to the bottom device, the first tier includes a first device and a first connection branch electrically coupled to the first device. Each of the N second bonding pairs includes a second tier and a third tier stacked upon the second tier, the second tier includes a second device and a second connection branch electrically coupled to the second device, and the third tier includes a third device and a third connection branch electrically coupled to the third device. The through tier via unitarily penetrates through the N second bonding pairs and the first tier of the first bonding pair, and the through tier via is electrically coupled to the front-side RDL and the first, second, and third connection branches, where N≥1.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A device package, comprising:
a first tier, comprising a first device and a first interconnect structure electrically coupled to the first device, the first interconnect structure comprising a first metal layer, and the first metal layer comprising a first connection branch;
a second tier, stacked upon the first tier, comprising a second device and a second interconnect structure electrically coupled to the second device, the second interconnect structure comprising a second metal layer, and the second metal layer comprising a second connection branch; and
a through tier via, unitarily penetrating through the first tier and the second tier, electrically coupled to the first connection branch and the second connection branch.

2. The device package of claim 1, wherein:
the first tier comprises a first-side bonding layer bonded to the second tier, and
the first interconnect structure of the first tier further comprises a first interlayer dielectric (ILD) layer distal to the first metal layer and directly connected to the first-side bonding layer.

3. The device package of claim 2, wherein:
the second tier comprises a first-side bonding layer bonded to the first tier, and
a first bonding interface is between the first-side bonding layer of the first tier and the first-side bonding layer of the second tier.

4. The device package of claim 3, wherein:
the first ILD layer comprises a first-side surface distal to the first bonding interface, and
a vertical distance between the first-side surface and the first bonding interface is less than 2 micrometers.

5. The device package of claim 3, wherein:
the first-side bonding layer of the second tier is proximal to the second metal layer of the second tier, and
the second tier and the first tier are bonded in a front-to-back configuration.

6. The device package of claim 3, wherein:
the first-side bonding layer of the second tier is distal to the second metal layer of the second tier, and
the second tier and the first tier are bonded in a back-to-back configuration.

7. The device package of claim 1, wherein the first device and the second device are capacitors or inductors.

8. The device package of claim 1, wherein the first and second devices are back-end-of-line (BEOL) devices.

9. The device package of claim 1, wherein:
the first connection branch comprises a first metal segment and a first hollow region surrounded by the first metal segment,
the second connection branch comprises a second metal segment and a second hollow region surrounded by the second metal segment, and
the first metal segment and the second metal segment are electrically coupled to the through tier via.

10. The device package of claim 9, wherein:
the first hollow region comprises a first width,
the second hollow region comprises a second width, and
the first width is less than the second width.

11. The device package of claim 9, wherein:
the through tier via comprises a first sidewall interfaced with the second metal segment and a second sidewall extending between the first metal segment and the second metal segment, and
a slope of the second sidewall is greater than a slope of the first sidewall.

12. The device package of claim 1, further comprising:
a bottom tier, underlying the first tier, the bottom tier comprising a bottom device, a bottom interconnect structure electrically coupled to the bottom device, and a front-side redistribution layer (RDL) electrically coupled to the through tier via.

13. The device package of claim 12, wherein the through tier via directly lands on the front-side RDL of the bottom tier.

14. The device package of claim 12, wherein the bottom device of the bottom tier is a logic device.

15. The device package of claim 12, wherein:
the bottom tier further comprises a second-side bonding layer proximal to the front-side RDL,
the first tier further comprises a second-side bonding layer proximal to the first metal layer,
a second bonding interface is between the second-side bonding layer of the bottom tier and the second-side bonding layer of the first tier, and
the first tier and the bottom tier are bonded in a front-to-front configuration.

16. The device package of claim 1, further comprising:
a passivation structure, overlying the second tier; and
a conductive structure, in the passivation structure, comprising:
a RDL electrically coupled to the through tier via; and
a conductive pad electrically coupled to the RDL and exposed by the passivation structure.

17. The device package of claim 1, further comprising:
an additional through tier via, penetrating through the first and second tiers, wherein one of the first and second tiers further comprises an additional connection branch connected to the additional through tier via.

18. The device package of claim 17, wherein the additional connection branch is electrically isolated from one of the first and second devices of the corresponding one of the first and second tiers.

19. A device package, comprising:
a first bonding pair, comprising a bottom tier and a first tier stacked upon the bottom tier, the bottom tier comprising a bottom device and a front-side RDL electrically coupled to the bottom device, the first tier comprising a first device and a first connection branch electrically coupled to the first device;
N second bonding pairs, stacked upon the first bonding pair, each of the N second bonding pairs comprising a second tier and a third tier stacked upon the second tier, the second tier comprising a second device and a second connection branch electrically coupled to the second device, the third tier comprising a third device and a third connection branch electrically coupled to the third device; and
a through tier via, unitarily penetrating through the N second bonding pairs and the first tier of the first bonding pair, electrically coupled to the front-side RDL and the first, second, and third connection branches,
wherein N≥1.

20. The device package of claim 19, wherein:
the bottom tier and the first tier are bonded in a front-to-front configuration,
the second tier and the third tier are bonded in the front-to-front configuration, and
the first tier and a tier of the N second bonding pairs bonded to the first tier are bonded in a back-to-back configuration.
